(19) United States
(12) Patent Application Publication
(10) Pub. No.: US 2026/0040784 A1
(43) Pub. Date: Feb. 5, 2026

(54) DISPLAY DEVICE AND ELECTRONIC DEVICE INCLUDING THE SAME

(71) Applicant: Samsung Display Co., Ltd., Yongin-Si (KR)

(72) Inventors: DAEGEUN LEE, Yongin-si (KR); SUJEONG KIM, Yongin-si (KR); EUNJEONG JEON, Yongin-si (KR); SEOUNGBUM PYOUN, Yongin-si (KR)

(21) Appl. No.: 19/242,095

(22) Filed: Jun. 18, 2025

(30) Foreign Application Priority Data
Aug. 2, 2024 (KR) 10-2024-0103143

(51) Int. Cl. H10K 59/131; H10K 59/95

(52) U.S. Cl. CPC H10K 59/131; H10K 59/95

(57) ABSTRACT

A display device includes a display panel including a non-display region in which a plurality of pad electrodes are disposed, and a driving unit including a plurality of bump electrodes. The bump electrodes include a plurality of first bump electrodes and a plurality of second bump electrodes. Each of the first bump electrodes and the second bump electrodes includes a plurality of protruding members, and a bonding layer covering the plurality of protruding members. A first area of each of the plurality of first bump electrodes is larger than a second area of each of the plurality of second bump electrodes. A first contact area between the bonding layer of each of the first bump electrodes and a first pad electrode is larger than a second contact area between the bonding layer of each of the second bump electrodes and a second pad electrode.

### CROSS-REFERENCE TO RELATED APPLICATIONS

This application claims priority under 35 U.S.C. § 119 to Korean Patent Application No. 10-2024-0103143, filed on Aug. 2, 2024, the entire contents of which are hereby incorporated by reference.

### BACKGROUND

The present disclosure herein relates to a display device including a driving unit and a bump electrode and an electronic device including the same.

Electronic devices such as smart phones, digital cameras, notebook computers, navigation systems, and smart televisions that provide images to users include a display device for displaying images. The display device generates images and provides the images to users through a display screen.

The display device includes a display panel that displays images. The display panel includes a plurality of gate lines, a plurality of data lines, and a plurality of pixels connected to the plurality of gate lines and the plurality of data lines.

The display panel may be connected to a driving unit that provides the gate lines or the data lines with electrical signals necessary for displaying images.

### SUMMARY

The present disclosure provides a display device and an electronic device with improved electrical connection characteristics between a pad electrode and a bump electrode.

According to an embodiment of the present disclosure, a display device includes a display panel including a display region in which pixels are disposed and a non-display region in which a plurality of pad electrodes are disposed, and a driving unit disposed on the display panel and including a plurality of bump electrodes each of which connects to a corresponding pad electrode among the plurality of pad electrodes. The plurality of bump electrodes include a plurality of first bump electrodes arranged along a first direction, and a plurality of second bump electrodes spaced apart from the plurality of first bump electrodes along a second direction crossing the first direction and arranged along the first direction. Each of the plurality of first bump electrodes and the plurality of second bump electrodes includes a plurality of protruding members protruding to be adjacent to the display panel, and a bonding layer covering the plurality of protruding members and including a metal. The bonding layer of each of the plurality of first bump electrodes is partially in contact with a first pad electrode among the plurality of pad electrodes, and the bonding layer of each of the plurality of second bump electrodes is partially in contact with a second pad electrode among the plurality of pad electrodes. A first area of each of the plurality of first bump electrodes is larger than a second area of each of the plurality of second bump electrodes. A first contact area between the bonding layer of each of the plurality of first bump electrodes and the first pad electrode is larger than a second contact area between the bonding layer of each of the plurality of the second bump electrodes and the second pad electrode.

In an embodiment, the display device may further include a first adhesive layer that is disposed between the display panel and the driving unit and bonds the display panel to the driving unit. The first adhesive layer may include a non-conductive film.

In an embodiment, the driving unit may further include a driving integrated circuit, and a driving pad disposed below a lower surface of the driving integrated circuit. The plurality of bump electrodes may be disposed below the lower surface of the driving integrated circuit.

In an embodiment, each of the plurality of first bump electrodes and the plurality of second bump electrodes may further include an intermediate layer disposed between the plurality of protruding members and the bonding layer and electrically connected to the driving pad.

In an embodiment, the first pad electrode may overlap each of the plurality of first bump electrodes on a plane, and the second pad electrode may overlap each of the plurality of second bump electrodes on the plane.

In an embodiment, a planar area of each of the plurality of protruding members in each of the plurality of first bump electrodes may be larger than a planar area of each of the plurality of protruding members in each of the plurality of second bump electrodes.

In an embodiment, the number of the plurality of protruding members in each of the plurality of first bump electrodes may be greater than the number of the plurality of second protruding members in each of the plurality of second bump electrodes.

In an embodiment, each of the plurality of protruding members in each of the plurality of first bump electrodes may be arranged side by side in the second direction, and each of the plurality of second protruding members in each of the plurality of second bump electrodes may be arranged side by side in the second direction.

In an embodiment, the driving unit may include a first long side extending in the first direction, a second long side extending in the first direction and spaced apart from the first long side along the second direction, a first short side extending in the second direction and connecting the first long side and the second long side to each other, and a second short side extending in the second direction and spaced apart from the first short side along the first direction. The plurality of first bump electrodes may be disposed adjacent to the first long side, and the plurality of second bump electrodes may be disposed adjacent to the second long side.

In an embodiment, the plurality of bump electrodes may further include a plurality of third bump electrodes disposed adjacent to at least one of the first short side and the second short side and arranged along the second direction.

In an embodiment, a third area of each of the plurality of third bump electrodes may be larger than the second area.

In an embodiment, each of the plurality of third bump electrodes may include a plurality of third protruding members protruding to be adjacent to the display panel, and a third bonding layer covering the plurality of protruding members, including a metal, and being partially in contact with one of the plurality of pad electrodes. A third contact area between the third bonding layer of each of the plurality of third bump electrodes and one of the plurality of pad electrodes may be larger than the second contact area.

In an embodiment, the first area may be about 1.5 to about 3 times larger than the second area.

In an embodiment, the number of the plurality of first bump electrodes included in the driving unit may be less than the number of the plurality of second bump electrodes included in the driving unit.

In an embodiment, the plurality of protruding members may include a polymer material.

In an embodiment, a width of each of the plurality of protruding members may decrease as each of the plurality of protruding members approaches the display panel.

In an embodiment, the plurality of second bump electrodes may be disposed closer to the display region than the plurality of first bump electrodes.

According to an embodiment, a display device includes a display panel including a display region in which pixels are disposed and a non-display region in which a plurality of pad electrodes are disposed, and a driving unit disposed on the display panel and including a plurality of bump electrodes each of which connects to a corresponding pad electrode among the plurality of pad electrodes. The plurality of bump electrodes include a plurality of first bump electrodes arranged along a first direction, and a plurality of second bump electrodes arranged along the first direction. The plurality of first bump electrodes are spaced apart from the display region with the plurality of second bump electrodes interposed between the plurality of first bump electrodes and the display region. Each of the plurality of first bump electrodes and the plurality of second bump electrodes includes a plurality of protruding members protruding to be adjacent to the display panel, and a bonding layer covering the plurality of protruding members. The bonding layer of each of the plurality of first bump electrodes is partially in contact with a first pad electrode among the plurality of pad electrodes, and the bonding layer of each of the plurality of second bump electrodes is partially in contact with a second pad electrode among the plurality of pad electrodes. A first area of each of the plurality of first bump electrodes is different from a second area of each of the plurality of second bump electrodes. A first contact area between the bonding layer of each of the plurality of first bump electrodes and the first pad electrode is different from a second contact area between the bonding layer of each of the plurality of second bump electrodes and the second pad electrode.

In an embodiment, the first pad electrode may overlap each of the plurality of first bump electrodes on a plane, and the second pad electrode may overlap each of the plurality of second bump electrodes on the plane. Each of the plurality of first bump electrodes may include a plurality of first protruding members protruding to be adjacent to the display panel, and a first bonding layer covering the plurality of first protruding members, including a metal, and being partially in contact with the first pad electrode. Each of the plurality of second bump electrodes may include a plurality of second protruding members protruding to be adjacent to the display panel, and a second bonding layer covering the plurality of second protruding members, including a metal, and being partially in contact with the plurality of second pad electrode.

According to an embodiment, an electronic device includes a display panel including a display region in which pixels are disposed and a non-display region in which a plurality of pad electrodes are disposed, a driving unit disposed on the display panel and including a plurality of bump electrodes each of which connects to a corresponding pad electrode among the plurality of pad electrodes, and a first adhesive layer disposed between the display panel and the driving unit and bonding the display panel to the driving unit. The first adhesive layer includes a non-conductive film. The plurality of bump electrodes include a plurality of first bump electrodes arranged along a first direction, and a plurality of second bump electrodes arranged along the first direction. Each of the plurality of first bump electrodes and the plurality of second bump electrodes includes a plurality of protruding members protruding to be adjacent to the display panel, and a bonding layer covering the plurality of protruding members. The bonding layer of each of the plurality of first bump electrodes is partially in contact with a first pad electrode among the plurality of pad electrodes, and the bonding layer of each of the plurality of second bump electrodes is partially in contact with a second pad electrode among the plurality of pad electrodes. A first area of each of the plurality of first bump electrodes is different from a second area of each of the plurality of second bump electrodes. A first contact area between the bonding layer of each of the plurality of first bump electrodes and the first pad electrode is different from a second contact area between the bonding layer of each of the plurality of the second bump electrodes and the second pad electrode.

### BRIEF DESCRIPTION OF THE DRAWINGS

The accompanying drawings are included to provide a further understanding of the present disclosure, and illustrate an embodiment of the present disclosure, together with the following description, to explain features of the present disclosure.

FIG. 1 is a perspective view of an electronic device according to an embodiment of the present disclosure.

FIG. 2 is an exploded perspective view of the electronic device according to an embodiment of the present disclosure.

FIG. 3 is a cross-sectional view of a display device according to an embodiment of the present disclosure.

FIG. 4 is a plan view of a display panel according to an embodiment of the present disclosure.

FIG. 5 is a cross-sectional view of a pixel according to an embodiment of the present disclosure.

FIG. 6 is a side view of the display device according to an embodiment of the present disclosure.

FIG. 7 is an enlarged perspective view of a portion of the display device according to an embodiment of the present disclosure.

FIG. 8 is a plan view of a driving unit according to an embodiment of the present disclosure.

FIG. 9A is a plan view of one of first bump electrodes included in the driving unit according to an embodiment of present disclosure.

FIG. 9B is a plan view of one of second bump electrodes included in the driving unit according to an embodiment of the present disclosure.

FIG. 9C is a plan view of one of third bump electrodes included in the driving unit according to an embodiment of the present disclosure.

Each of FIGS. 10A to 10C is a cross-sectional view of a portion of the display device according to an embodiment of the present disclosure.

FIG. 11 is a plan view of a driving unit according to an embodiment of the present disclosure.

FIG. 12A is a plan view of one of first bump electrodes included in the driving unit according to an embodiment of the present disclosure.

FIG. 12B is a plan view of one of second bump electrodes included in the driving unit according to an embodiment of the present disclosure.

FIG. 12C is a plan view of one of third bump electrodes included in the driving unit according to an embodiment of the present disclosure.

Each of FIGS. 13A to 13C is a cross-sectional view of a portion of the display device according to an embodiment of the present disclosure.

FIG. 14 is a block diagram of an electronic device according to one embodiment.

FIG. 15 is a schematic diagram of an electronic device according to various embodiments.

### DETAILED DESCRIPTION

In this specification, it will be understood that when an element (or region, layer, portion, etc.) is referred to as being “on”, “connected to” or “coupled to” another element, it can be directly on, connected or coupled to the other element, or indirectly on, connected or coupled to the other element with an intervening element therebetween.

Like reference numerals refer to like elements throughout this specification. In addition, in the drawings, the thicknesses, ratios, and dimensions of elements are exaggerated for effective description of the technical contents. As used herein, the term “and/or” includes any and all combinations that the associated configurations can define.

It will be understood that, although the terms first, second, etc. may be used herein to describe various elements, these elements should not be limited by these terms. These terms are only used to distinguish one element from another element. For example, a first element could be referred to as a second element without departing from the scope of the present invention. Similarly, the second element may also be referred to as the first element. The terms of a singular form include plural forms unless clearly indicated otherwise.

In addition, terms, such as “below”, “lower”, “above”, “upper” or the like, are used herein for ease of description to describe the spatial relation between one element and other element(s) as illustrated in the drawings. The above terms are relative concepts and are described based on the directions indicated in the drawings.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

In this specification, the expression “being directly disposed” may mean that there is no layer, film, region, plate, or the like between a part of a layer, film, region, plate, or the like and another part. For example, the expression “being directly disposed” may mean being disposed between two layers or two members without an additional member such as an adhesive member interposed therebetween.

Unless defined otherwise, all terms (including technical and scientific terms) used herein have the same meaning as commonly understood by one of ordinary skill in the art to which the present disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, an embodiment of the present disclosure will be described with reference to the drawings.

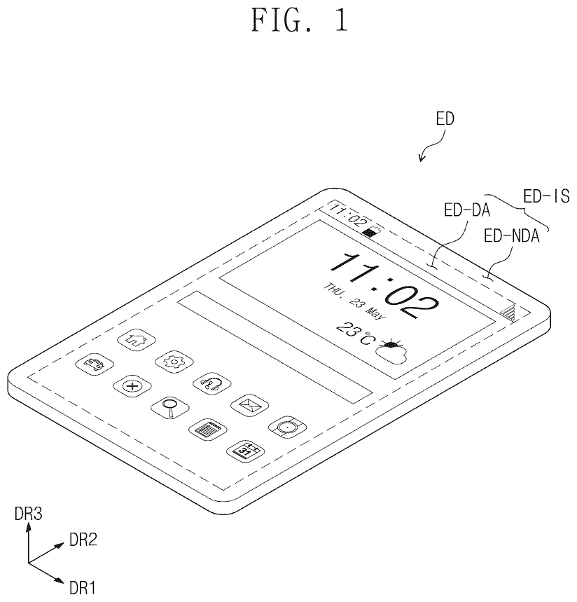

FIG. 1 is a perspective view of an electronic device according to an embodiment of the present disclosure.

Referring to FIG. 1, the electronic device ED may have a rectangular shape with short sides extending in a first direction DR1 and long sides extending in a second direction DR2 crossing the first direction DR1. However, the embodiment of the present disclosure is not limited thereto, and the electronic device ED may have various shapes such as a circle and a polygon.

Hereinafter, a direction substantially perpendicular to a plane defined by the first direction DR1 and the second direction DR2 is defined as a third direction DR3. In addition, in this specification, the expression “when viewed on a plane” may be defined as a state of being viewed from the third direction DR3.

The upper surface of the electronic device ED may be defined as a display surface ED-IS, and the display surface ED-IS may have a plane defined by the first direction DR1 and the second direction DR2. Images IM generated in the electronic device ED may be provided to a user through the display surface ED-IS.

The display surface ED-IS may include a display region ED-DA and a non-display region ED-NDA surrounding the display region ED-DA. The display region ED-DA may display an image, and the non-display region ED-NDA may not display an image. The non-display region ED-NDA may surround the display region ED-DA and define a boundary of the electronic device ED that has a predetermined color.

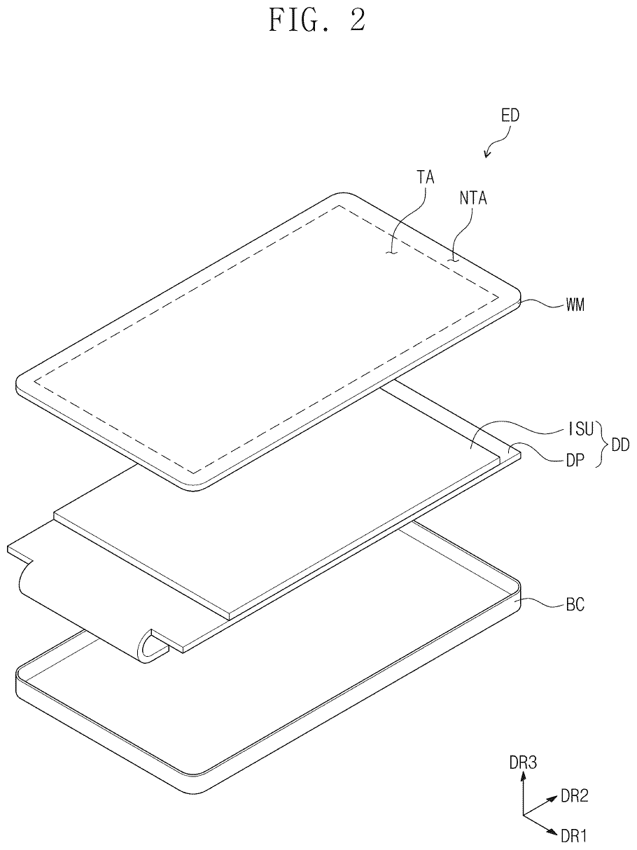

FIG. 2 is an exploded perspective view of the electronic device according to an embodiment of the present disclosure.

Referring to FIG. 2, the electronic device ED may include a window WM, a display device DD, and a housing BC. The housing BC may accommodate the display device DD and be coupled to the window WM. Although not illustrated, the electronic device ED may further include other electronic modules accommodated in the housing BC and electrically connected to a display panel DP. For example, the electronic device ED may further include a main board, a circuit module mounted on the main board, a camera module, a power module, etc.

The window WM may be disposed on the display device DD. The window WM may transmit an image provided from the display device DD to the outside. The window WM may include a transmissive region TA and a non-transmissive region NTA. The transmissive region TA may overlap the display region ED-DA of FIG. 1. The transmissive region TA may have a shape corresponding to the display region ED-DA.

The non-transmissive region NTA may overlap the non-display region ED-NDA (see FIG. 1) and have a shape corresponding to the non-display region ED-NDA (see FIG. 1). The non-transmissive region NTA may have a relatively low light transmittance compared to the transmissive region TA.

The display device DD may generate an image and sense an external input. The display device DD may include a display panel DP and an input sensor ISU. Although not illustrated, the display device DD may further include an anti-reflection member disposed on the input sensor ISU. The anti-reflection member may include a polarizer and a retarder, or a color filter and a black matrix.

The display panel DP may be a light-emitting display panel. However, the type of the display panel DP may not be particularly limited thereto. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include a quantum dot, a quantum rod, a nano LED, etc. Hereinafter, the display panel DP is described as an organic light-emitting display panel.

The input sensor ISU may include any one of a capacitive sensor, an optical sensor, an ultrasonic sensor, and an electromagnetic induction sensor. The input sensor ISU may be formed on the display panel DP through a continuous manufacturing process, or may be manufactured separately and then attached to the upper side of the display panel DP by an adhesive layer.

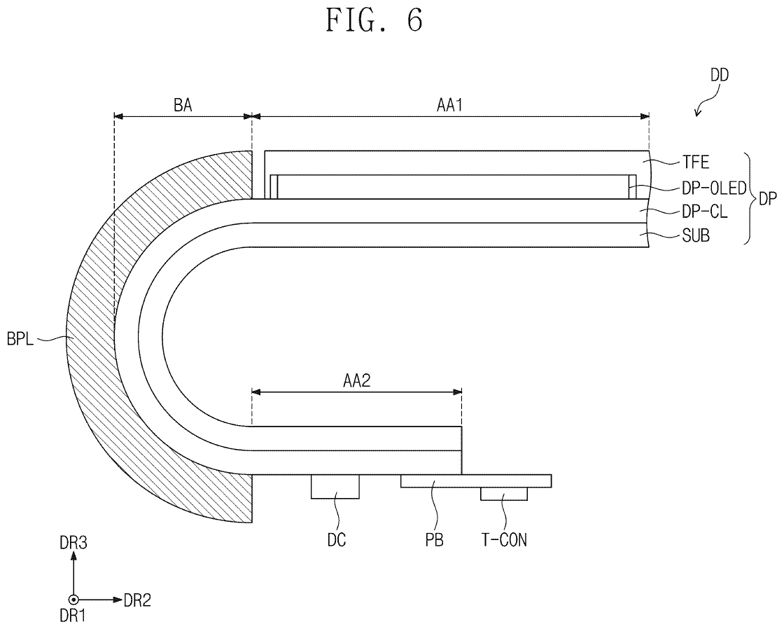

In the display device DD according to an embodiment of the present disclosure, a portion of the display panel DP may be bent so that a driving unit DC (see FIG. 6) is directed downward. The non-display region ED-NDA (see FIG. 1) of the display panel DP may be bent. However, a bent portion is not limited thereto, and a circuit board PB (see FIG. 6) may be bent while the display panel may not be bent.

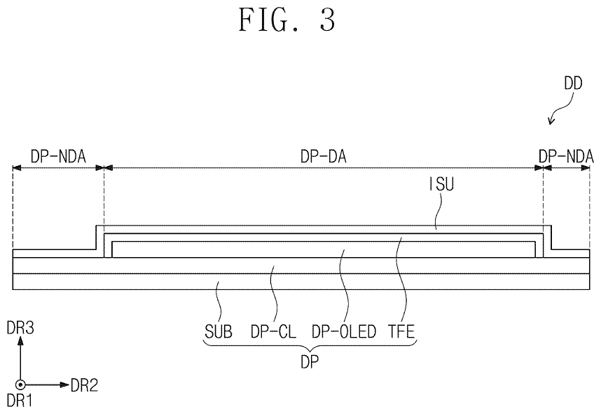

FIG. 3 is a cross-sectional view of a display device according to an embodiment of the present disclosure.

Referring to FIG. 3, the display panel DP may include a substrate SUB, a circuit element layer DP-CL disposed on the substrate SUB, a display element layer DP-OLED, and a thin-film encapsulation layer TFE. The input sensor ISU may be disposed on the thin-film encapsulation layer TFE.

The substrate SUB may include a display region DP-DA and a non-display region DP-NDA surrounding the display region DP-DA. The substrate SUB may include a flexible plastic material such as glass or polyimide (PI). The display element layer DP-OLED may be disposed on the display region DP-DA.

A plurality of pixels may be disposed on the circuit element layer DP-CL and the display element layer DP-OLED. Although not illustrated, each of the pixels may include a plurality of transistors and at least one capacitor disposed in the circuit element layer DP-CL, and a light-emitting element disposed in the display element layer DP-OLED and connected to a transistor.

The thin-film encapsulation layer TFE may be disposed on the circuit element layer DP-CL to cover the display element layer DP-OLED. The thin-film encapsulation layer TFE may protect the pixels from moisture, oxygen, and external foreign substances.

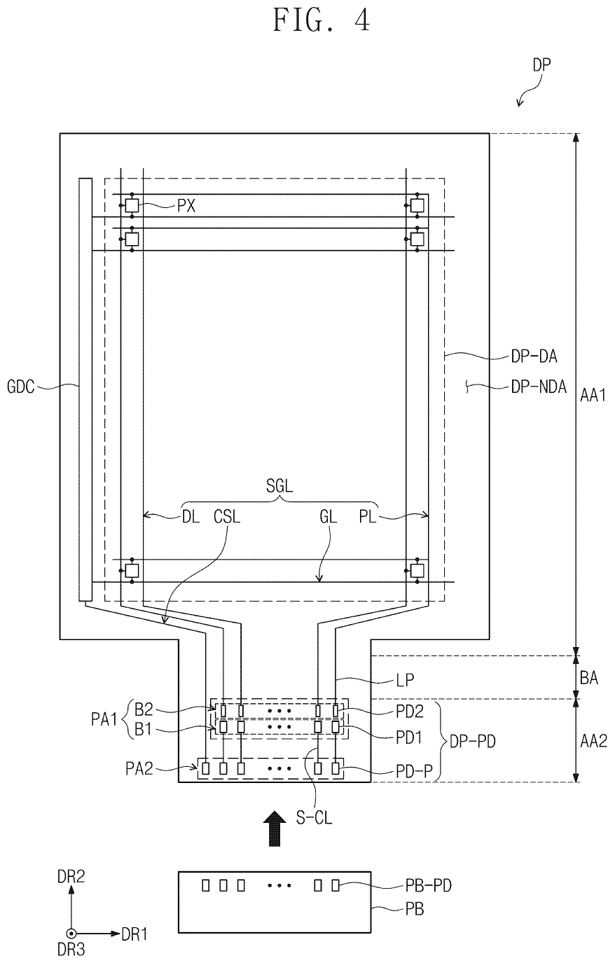

FIG. 4 is a plan view of a display panel according to an embodiment of the present disclosure. FIG. 4 illustrates a planar shape of the display panel DP illustrated in FIG. 3.

Referring to FIG. 4, the display panel DP may include a plurality of pixels PX, a gate driving circuit GDC, a plurality of signal lines SGL, and a plurality of pad electrodes DP-PD.

The display panel DP may include a first portion AA1, a second portion AA2, and a bending portion BA disposed between the first portion AA1 and the second portion AA2. The first portion AA1, the bending portion BA, and the second portion AA2 may be sequentially arranged along the second direction DR2. The bending portion BA may extend from the first portion AA1 in the second direction DR2, and the second portion AA2 may extend from the bending portion BA in the second direction DR2.

The first portion AA1 may extend in the second direction DR2 and have long sides spaced apart from each other in the first direction DR1. Along the first direction DR1, the widths of the bending portion BA and the second portion AA2 may be smaller than the width of the first portion AA1.

The pixels PX may be disposed in the display region DP-DA. Each of the pixels PX includes an organic light-emitting element and a pixel driving circuit connected thereto. The gate driving circuit GDC sequentially outputs gate signals to a plurality of gate lines GL to be described later. The transistor of the gate driving circuit GDC may be formed through the same process as the transistor of the pixel PX, such as a low temperature polycrystalline silicon (LTPS) process or a low temperature polycrystalline oxide (LTPO) process. The display panel DP may further include another driving circuit that provides a light-emitting control signal to the pixels PX.

The signal lines SGL may include gate lines GL, data lines DL, a power line PL, and a control signal line CSL. Each of the gate lines GL may be connected to a corresponding pixel PX among the pixels PX, and each of the data lines DL may be connected to a corresponding pixel PX among the pixels PX. The power line PL may be connected to the pixels PX. The control signal line CSL may provide control signals to a gate driving circuit GDC.

The signal lines SGL may overlap the display region DP-DA and the non-display region DP-NDA. Each of the signal lines SGL may include a line portion LP. The line portion LP may overlap the display region DP-DA and the non-display region DP-NDA.

The plurality of pad electrodes DP-PD may be disposed in the second portion AA2 of the non-display region DP-NDA. The plurality of pad electrodes DP-PD may include first pad electrodes PD1, second pad electrodes PD2, and substrate-side pad electrodes PD-P. A region in which the first and second pad electrodes PD1 and PD2 are disposed may be defined as a first pad region PA1, and a region in which the substrate-side pad electrodes PD-P are disposed may be defined as a second pad region PA2.

The first pad region PA1 may overlap a driving unit DC (see FIG. 6), and the second pad region PA2 may overlap a circuit board PB. The first pad region PA1 may include a first region B1 in which the first pad electrodes PD1 are disposed and a second region B2 in which the second pad electrodes PD2 are disposed. The first pad electrodes PD1 may have a larger planar area than the second pad electrodes PD2. The first pad region PA1 and the second pad region PA2 may be disposed within the non-display region DP-NDA. The first pad region PA1 and the second pad region PA2 may be spaced apart from each other in the second direction DR2. The first pad region PA1 may be closer to the display region DP-DA than the second pad region PA2, and the second pad region PA2 may be spaced apart from the display region DP-DA with the first pad region PA1 interposed therebetween.

Each of the second pad electrodes PD2 may be connected to a corresponding data line DL among the data lines DL. Although not illustrated, the first pad electrodes PD1 and the second pad electrodes PD2 may be electrically connected to each other. The first pad electrodes PD1 may be connected to the substrate-side pad electrodes PD-P through connection signal lines S-CL.

The circuit board PB may include a plurality of circuit pads PB-PD. The circuit pads PB-PD may be arranged in the first direction DR1. The circuit pads PB-PD of the circuit board PB may be in contact with and connected to the substrate-side pad electrodes PD-P of the second pad region PA2.

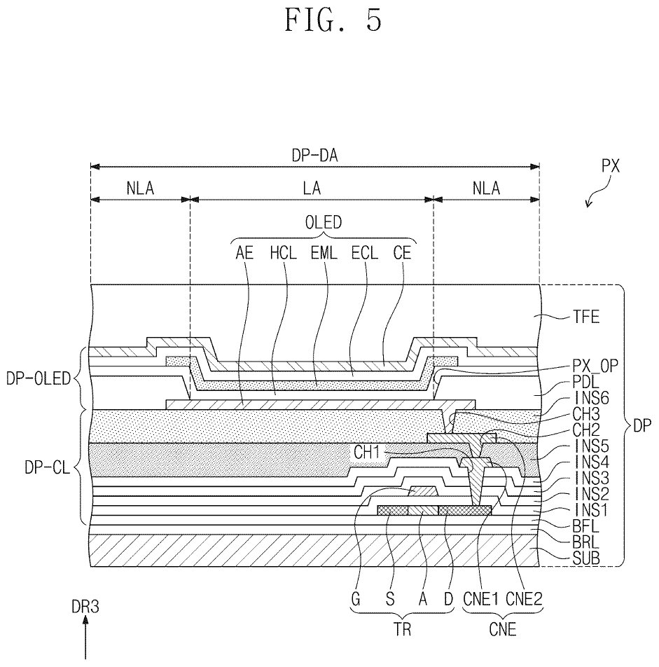

FIG. 5 is a cross-sectional view of a pixel according to an embodiment of the present disclosure.

Referring to FIGS. 4 and 5, the pixel PX may include a transistor TR and a light-emitting element OLED. The light-emitting element OLED may include a first electrode AE (or anode), a second electrode CE (or cathode), a hole control layer HCL, an electron control layer ECL, and a light-emitting layer EML.

The transistor TR and the light-emitting element OLED may be disposed on the substrate SUB. Although one transistor TR is illustrated as an example, the pixel PX may include a plurality of transistors and at least one capacitor for driving the light-emitting element OLED. The plurality of transistors and at least the one capacitor may be connected to each other.

The display region DP-DA may include a light-emitting region LA corresponding to each of the pixels PX and a non-light-emitting region NLA surrounding the light-emitting region LA. The light-emitting element OLED may be disposed in the light-emitting region LA.

The substrate SUB may include polyimide (PI) as a flexible plastic material. A barrier layer BRL may be disposed on the substrate SUB. A buffer layer BFL may be disposed on the barrier layer BRL. The barrier layer BRL and the buffer layer BFL may be inorganic layers.

A semiconductor pattern may be disposed on the buffer layer BFL. The semiconductor pattern may include polysilicon, amorphous silicon, or a metal oxide. The semiconductor pattern may be doped with an N-type dopant or a P-type dopant. The semiconductor pattern may include a highly doped region and a lightly doped region. The conductivity of the highly doped region may be greater than that of the lightly doped region, and the highly doped region may substantially serve as a source S and a drain D of the transistor TR. The lightly doped region may substantially correspond to an active A (or channel) of the transistor.

A source S, an active A, and a drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2. A fourth insulating layer INS4 may be disposed on the third insulating layer INS3.

A connection electrode CNE may include a first connection electrode CNE1 and a second connection electrode CNE2 to connect the transistor TR to the light-emitting element OLED. The first connection electrode CNE1 may be disposed on the fourth insulating layer INS4 and connected to the drain D through a first contact hole CH1 extending through the first to fourth insulating layers INS1 to INS4.

A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 through a second contact hole CH2 extending through in the fifth insulating layer INS5. The second connection electrode CNE2 may be the data line DL of FIG. 4.

A sixth insulating layer INS6 may be disposed on the second connection electrode CNE2. The layers from the buffer layer BFL to the sixth insulating layer INS6 may be defined as a circuit element layer DP-CL. The first insulating layer INS1 to the sixth insulating layer INS6 may be inorganic or organic layers.

The first electrode AE may be disposed on the sixth insulating layer INS6. The first electrode AE may be connected to the second connection electrode CNE2 through a third contact hole CH3 extending through the sixth insulating layer INS6. The first electrode AE may be connected to the transistor TR through the first and second connection electrodes CNE1 and CNE2. A pixel defining film PDL which includes an opening PX_OP extending to a predetermined portion of the first electrode AE may be disposed on the first electrode AE and the sixth insulating layer INS6.

The hole control layer HCL may be disposed on the first electrode AE and the pixel defining film PDL. The hole control layer HCL may include a hole transport layer and a hole injection layer.

The light-emitting layer EML may be disposed on the hole control layer HCL. The light-emitting layer EML may be disposed in a region corresponding to the opening PX_OP. The light-emitting layer EML may include an organic material and/or an inorganic material. The light-emitting layer EML may generate light of any one of red, green, and blue.

The electron control layer ECL may be disposed on the light-emitting layer EML and the hole control layer HCL. The electron control layer ECL may include an electron transport layer and an electron injection layer. The hole control layer HCL and the electron control layer ECL may be commonly disposed in the light-emitting region LA and the non-light-emitting region NLA.

The second electrode CE may be disposed on the electron control layer ECL. The second electrode CE may be commonly shared by the pixels PX. The layers including the light-emitting element OLED may be defined as a display element layer DP-OLED.

The thin-film encapsulation layer TFE may be disposed on the second electrode CE to cover the pixel PX (see FIG. 4). Although not illustrated, the thin-film encapsulation layer TFE may include a plurality of layers. Some of the layers may include inorganic insulating layers and protect the pixel PX (see FIG. 4) from moisture/oxygen. Some of the remaining layers may include organic insulating layers and protect the pixel PX (see FIG. 4) from foreign substances such as dust particles.

A first voltage may be applied to the first electrode AE through the transistor TR, and a second voltage having a lower level than the first voltage may be applied to the second electrode CE. Holes and electrons injected into the light-emitting layer EML may be combined with each other to form excitons, and the light-emitting element OLED may emit light while the excitons transition to a ground state.

FIG. 6 is a side view of the display device according to an embodiment of the present disclosure. FIG. 6 illustrates a state in which the bending portion BA is bent in the display panel DP of FIG. 4. FIG. 6 is a side view of the display device DD viewed in the first direction DR1.

Since a substrate SUB, a circuit element layer DP-CL, a display element layer DP-OLED, and a thin-film encapsulation layer TFE of FIG. 6 are the same as the substrate SUB, the circuit element layer DP-CL, the display element layer DP-OLED, and the thin-film encapsulation layer TFE of FIG. 5, the detailed descriptions thereof will be omitted.

The display device DD may include a driving unit DC, a circuit board PB, a bending protective layer BPL, and a timing controller T-CON.

The driving unit DC may be disposed on and be mounted on the display panel DP. However, the embodiment of the present disclosure is not limited thereto. The driving unit DC may generate a driving signal necessary for the operation of the display panel DP, based on a control signal transmitted from the circuit board PB.

The circuit board PB may be disposed on one end of the substrate SUB and electrically connected to the circuit element layer DP-CL. The timing controller T-CON may be disposed on the circuit board PB. The timing controller T-CON may be formed as an integrated circuit chip and mounted on the upper surface of the circuit board PB.

The bending portion BA may be bent so that the second portion AA2 is disposed below the first portion AA1. Therefore, the driving unit DC, the circuit board PB, and the timing controller T-CON may face a direction opposite to the third direction DR3 and be disposed below the second portion AA2.

The bending protective layer BPL may be disposed on the bending portion BA. The bending protective layer BPL may be disposed adjacent to the edges of the first and second portions AA1 and AA2. The bending protective layer BPL may be disposed to be spaced apart from the thin-film encapsulation layer TFE in the second direction DR2. The bending protective layer BPL may be bent together with the bending portion BA when the display panel DP is bent.

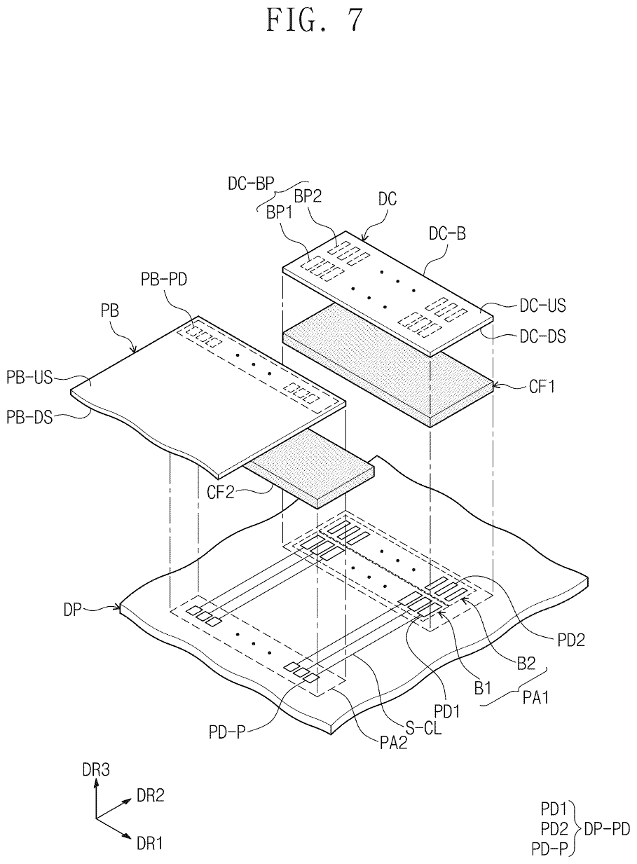

FIG. 7 is an enlarged perspective view of a portion of the display device according to an embodiment of the present disclosure. FIG. 7 illustrates an enlarged view of the driving unit DC, the circuit board PB, and the display panel DP disposed in the pad region PA illustrated in FIG. 4. For example, the driving unit DC and the circuit board PB of FIG. 7 are illustrated as being separated from the display panel DP.

Referring to FIG. 4 and FIG. 7, the driving unit DC may be bonded to the first pad region PA1 by a first adhesive layer CF1. The circuit board PB may be bonded to the second pad region PA2 by a second adhesive layer CF2.

Each of the first and second adhesive layers CF1 and CF2 may include synthetic resin having adhesive properties. Each of the first and second adhesive layers CF1 and CF2 may include a non-conductive film. Each of the first and second adhesive layers CF1 and CF2 may not include conductive particles such as conductive balls and may include a curable polymer material.

When the first adhesive layer CF1 is cured, the first and second pad electrodes PD1 and PD2 and the bump electrodes DC-BP may be fixed in a state of being in contact with each other. When the second adhesive layer CF2 is cured, the substrate-side pad electrodes PD-P and the circuit pads PB-PD may be fixed in a state of being in contact with each other.

The first pad region PA1 of the display panel DP may overlap the driving unit DC, and the second pad region PA2 may overlap the circuit board PB. The first pad region PA1 may include a first region B1 in which the first pad electrodes PD1 are disposed and a second region B2 in which the second pad electrodes PD2 are disposed. The first pad electrodes PD1 may have a larger planar area than the second pad electrodes PD2. The first pad region PA1 and the second pad region PA2 may be disposed within the non-display region DP-NDA. The first pad region PA1 and the second pad region PA2 may be spaced apart from each other in the second direction DR2.

The driving unit DC may be disposed on the first and second pad electrodes PD1 and PD2. The driving unit DC may include a driving integrated circuit DC-B, and the driving integrated circuit DC-B may include an upper surface DC-US and a lower surface DC-DS. The lower surface DC-DS of the driving unit DC may be a surface facing the first and second pad electrodes PD1 and PD2. The driving unit DC includes bump electrodes DC-BP electrically connected to the first pad electrodes PD1 and the second pad electrodes PD2 disposed on the substrate SUB. The bump electrodes DC-BP may be disposed on the lower surface DC-DS of the driving integrated circuit DC-B. The lower surface DC-DS of the driving integrated circuit DC-B may be a base surface on which the bump electrodes DC-BP are provided. The bump electrodes DC-BP may be disposed to correspond to the pad electrodes PD1 and PD2.

The bump electrodes DC-BP may include first bump electrodes BP1 and second bump electrodes BP2. The first bump electrodes BP1 may have a larger planar area than the second bump electrodes BP2. The first bump electrodes BP1 and the second bump electrodes BP2 may be spaced apart from each other in the second direction DR2. The first bump electrodes BP1 may be arranged in the first direction DR1. The second bump electrodes BP2 may be arranged in the first direction DR1. In FIG. 7, for the convenience of explanation, the planar shape of the bump electrodes DC-BP is illustrated with a dotted line on the upper surface DC-US of the driving unit DC, but each of the first bump electrodes BP1 and the second bump electrodes BP2 may have a shape that protrudes from the lower surface DC-DS of the driving unit DC and be exposed to the outside.

When the driving unit DC is bonded to the display panel DP by the first adhesive layer CF1, at least a portion of each of the first bump electrodes BP1 may come into contact with and be electrically connected to the first pad electrodes PD1 and at least a portion of each of the second bump electrodes BP2 may come into contact with and be electrically connected to the second pad electrodes PD2. The second bump electrodes BP2 may be disposed closer to the display region DP-DA (see FIG. 4) than the first bump electrodes BP1, and the first bump electrodes BP1 may be disposed to be spaced apart from the display region DP-DA (see FIG. 4) with the second bump electrodes BP2 interposed therebetween.

The driving unit DC may include a driving integrated circuit DC-B. The driving integrated circuit DC-B may be disposed on the bump electrodes DC-BP. The driving integrated circuit DC-B may be connected to the bump electrodes DC-BP. The driving unit DC may receive a first signal from the outside through the first pad electrodes PD1 and the first bump electrodes BP1. The driving unit DC may generate a second signal based on the first signal from the outside and provide the second signal to the second pad electrodes PD2 through the second bump electrodes BP2. The first signal may include an image signal, which is a digital signal applied from the outside, and the second signal may include a data signal which is an analog signal. The driving unit DC may generate an analog voltage corresponding to a grayscale value of the image signal. The data signal may be provided to the pixel PX through the data line DL illustrated in FIG. 4.

The circuit board PB may be disposed on the display panel DP. The circuit board PB may be disposed on the substrate-side pad electrodes PD-P. The circuit board PB may include an upper surface PB-US and a lower surface PB-DS. The lower surface PB-DS of the circuit board PB may be a surface facing the substrate-side pad electrodes PD-P. The circuit board PB may include a plurality of circuit pads PB-PD electrically connected to the substrate-side pad electrodes PD-P. The circuit pads PB-PD may be disposed on the lower surface PB-DS of the circuit board PB. The circuit pads PB-PD may be arranged in the first direction DR1. The circuit board PB may provide the driving unit DC with an image signal, a driving voltage, and other control signals.

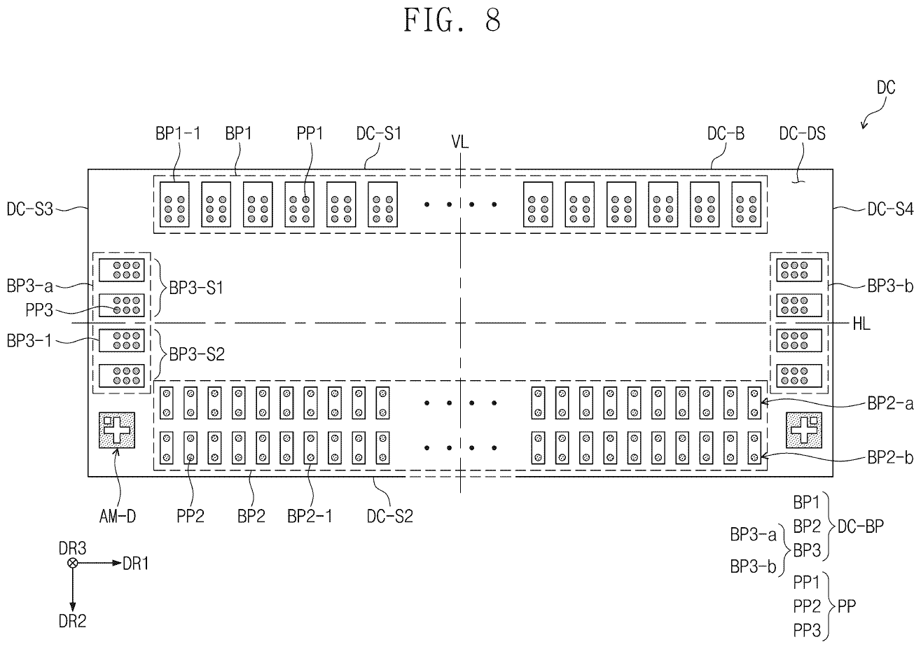

Hereinafter, with reference to FIG. 8, etc., a specific arrangement of the plurality of bump electrodes of the driving unit and their connection shapes with the pad electrodes will be described.

FIG. 8 is a plan view of the driving unit according to an embodiment of the present disclosure. In order to show the arrangement shape of the bump electrodes DC-BP of the driving unit DC, FIG. 8 illustrates a plane view of the lower surface DC-DS of the driving integrated circuit DC-B.

Referring to FIGS. 7 and 8, the driving unit DC may include a driving integrated circuit DC-B and a plurality of bump electrodes DC-BP disposed on the lower surface DC-DS of the driving integrated circuit DC-B. The bump electrodes DC-BP include a plurality of first bump electrodes BP1 and a plurality of second bump electrodes BP2.

Each of the plurality of first bump electrodes BP1 and the plurality of second bump electrodes BP2 may be arranged in the first direction DR1. The first bump electrodes BP1 and the second bump electrodes BP2 may be spaced apart from each other in the second direction DR2.

The driving unit DC may include two long sides DC-S1 and DC-S2 extending in the first direction DR1 and two short sides DC-S3 and DC-S4 extending in the second direction DR2, and the first bump electrodes BP1 and the second bump electrodes BP2 may be disposed adjacent to the long sides DC-S1 and DC-S2. The first bump electrodes BP1 may be disposed adjacent to the first long side DC-S1, and the second bump electrodes BP2 may be disposed adjacent to the second long side DC-S2. When the driving unit DC is bonded to the display panel DP, the second long side DC-S2 may be disposed adjacent to the aforementioned display region DP-DA (see FIG. 4), and the first long side DC-S1 may be spaced apart from the display region DP-DA (see FIG. 4) with the second long side DC-S2 interposed therebetween.

Each of the first bump electrodes BP1 may have a larger planar area than each of the second bump electrodes BP2. Each of the first bump electrodes BP1 and the second bump electrodes BP2 may have a rectangular shape on a plane. Each of the first bump electrodes BP1 may have a rectangular shape having a larger planar area than each of the second bump electrodes BP2.

At least one of the first bump electrodes BP1 and the second bump electrodes BP2 may have a plurality of bump rows. In the driving unit DC according to an embodiment of the present disclosure, the second bump electrodes BP2 may have two bump rows. Each of the second bump electrodes BP2 may include a first row BP2-a and a second row BP2-b extending in the first direction DR1. Unlike what is illustrated in FIG. 8, the second bump electrodes BP2 may have only one bump row, or may have three or more bump rows. In addition, the first bump electrodes BP1 may have a plurality of bump rows.

The bump electrodes DC-BP may further include a plurality of third bump electrodes BP3. The plurality of third bump electrodes BP3 may be disposed adjacent to the short sides DC-S3 and DC-S4 of the driving unit DC. The third bump electrodes BP3 may include left bump electrodes BP3-a disposed adjacent to the first short side DC-S3 and right bump electrodes BP3-b disposed adjacent to the second short side DC-S4. Each of the left bump electrodes BP3-a and the right bump electrodes BP3-b may be arranged along the second direction DR2. The left bump electrodes BP3-a and the right bump electrodes BP3-b may be spaced apart from each other in the first direction DR1.

The numbers of the plurality of first bump electrodes BP1 and the plurality of second bump electrodes BP2 included in the driving unit DC may be different from each other. In the driving unit DC according to an embodiment of the present disclosure, the number of the first bump electrodes BP1 may be smaller than that of the second bump electrodes BP2. The number of the plurality of second bump electrodes BP2 included in the driving unit DC may be greater than the number of the plurality of first bump electrodes BP1 and the number of the plurality of third bump electrodes BP3.

Each of the bump electrodes DC-BP may include a plurality of protruding members PP. Each of the plurality of protruding members PP may have a shape that protrudes so as to be adjacent to the display panel DP. That is, each of the plurality of protruding members PP may have a shape that protrudes in a direction opposite to the third direction DR3.

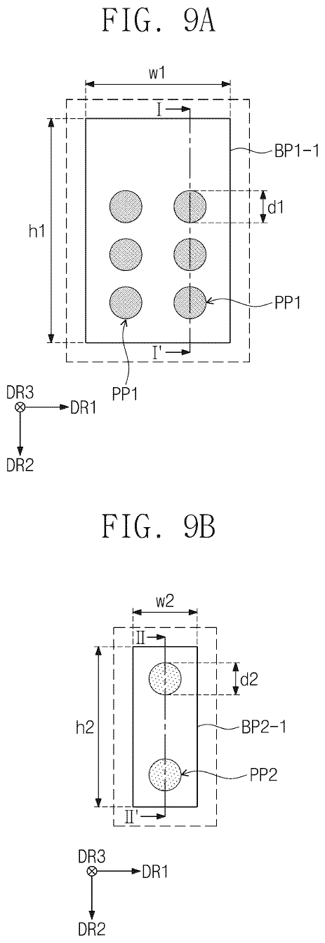

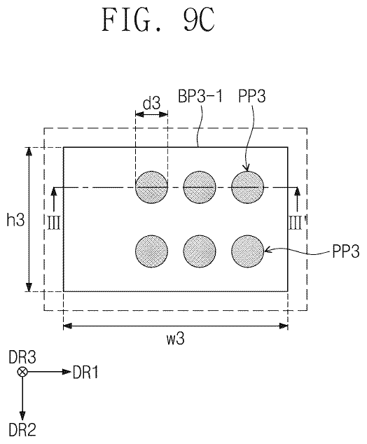

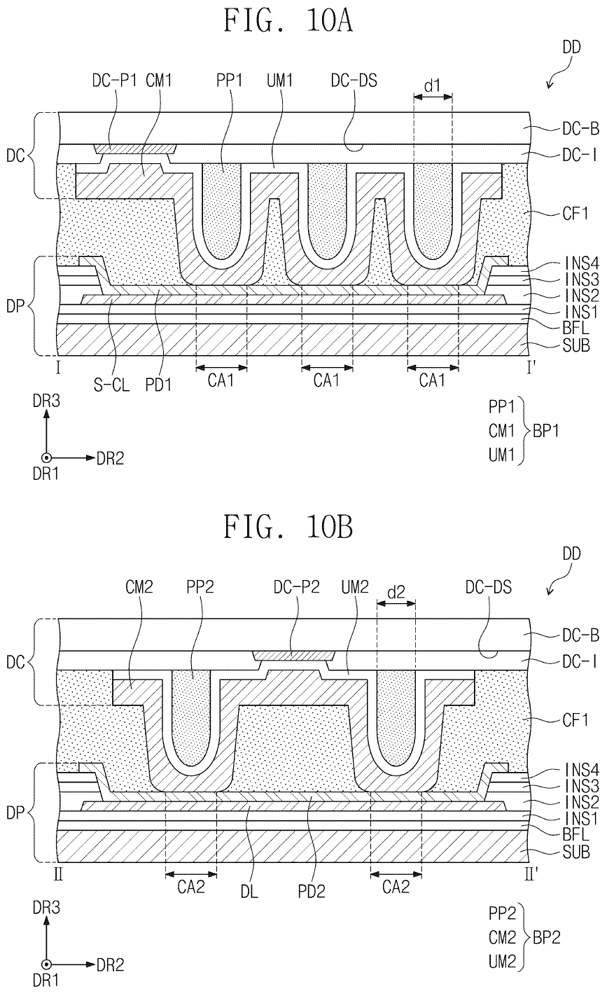

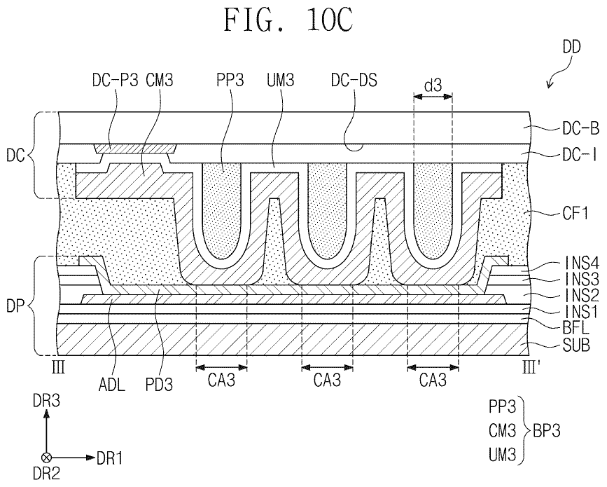

In the driving unit DC according to an embodiment of the present disclosure, a plurality of first protruding members PP1 included in each of the first bump electrodes BP1 and a plurality of second protruding members PP2 included in each of the second bump electrodes BP2 differ in the number of protruding members or in their planar areas. Accordingly, in the display device including the driving unit DC according to an embodiment of the present disclosure, the area of each of the first bump electrodes BP1 in contact with a corresponding pad electrode (for example, the first pad electrode PD1 of FIG. 7) and the area of each of the second bump electrodes BP2 in contact with a corresponding pad electrode (for example, the second pad electrode PD2 of FIG. 7) may be different from each other. The third bump electrodes BP3 may include a plurality of third protruding members PP3, and the third protruding members PP3 may differ from either the plurality of first protruding members PP1 or the plurality of second protruding members PP2 in the number of protruding members or in their planar areas. The detailed descriptions thereof will be provided later in FIG. 9A and below.

The driving unit DC may have a symmetrical shape with respect to a reference line VL extending along the second direction DR2. The reference line VL may extend along the second direction DR2 and extend to cross the center of each of the two long sides DC-S1 and DC-S2 of the driving unit DC. Each of the bump electrodes DC-BP included in the driving unit DC may be arranged to have a symmetrical shape with respect to the reference line VL. Each of the first bump electrodes BP1 and the second bump electrodes BP2 may be arranged along the first direction DR1 and may be arranged symmetrically with respect to the reference line VL. Each of the left bump electrodes BP3-a and the right bump electrodes BP3-b included in the third bump electrodes BP3 may be arranged along the second direction DR2, and the left bump electrodes BP3-a may be arranged symmetrically to the right bump electrodes BP3-b with respect to the reference line VL.

The driving unit DC may further include an alignment mark AM-D that is disposed adjacent to at least any one of the bump electrodes DC-BP in one direction. For example, the alignment mark AM-D may be adjacent to the second bump electrodes BP2 in the first direction DR1 and the third bump electrodes BP3 in the second direction DR2. The alignment mark AM-D may be used as an identification mark to check the position of the driving unit DC or to align the driving unit DC with the display panel DP in a process of bonding the driving unit DC to the display panel DP. In FIG. 8, the alignment mark AM-D is illustrated as including a cross shape and a square shape. However, the present disclosure is not limited thereto. For example, the alignment mark AM-D may be formed in various shapes as long as it is used to align each component.

FIG. 9A is a plan view of one of the first bump electrodes included in the driving unit according to an embodiment of the present disclosure. FIG. 9B is a plan view of one of the second bump electrodes included in the driving unit according to an embodiment of the present disclosure. FIG. 9C is a plan view of one of the third bump electrodes included in the driving unit according to an embodiment of the present disclosure. FIG. 9A illustrates an enlarged view of one of the first bump electrodes BP1-1 among the plurality of first bump electrodes BP1 illustrated in FIG. 8, FIG. 9B illustrates an enlarged view of one of the second bump electrodes BP2-1 among the plurality of second bump electrodes BP2 illustrated in FIG. 8, and FIG. 9C illustrates an enlarged view of one of the third bump electrodes BP3-1 among the plurality of third bump electrodes BP3 illustrated in FIG. 8.

Referring to FIG. 8, FIG. 9A, and FIG. 9B together, the first bump electrode BP1-1 may have a larger planar area than the second bump electrode BP2-1. The first bump electrode BP1-1 may have a first width w1 in the first direction DR1, a first length h1 in the second direction DR2, and a first area on a plane. The second bump electrode BP2-1 may have a second width w2 in the first direction DR1, a second length h2 in the second direction DR2, and a second area on a plane. In an embodiment of the present disclosure, the first width w1 may be greater than the second width w2. The first area may be larger than the second area. For example, the first area may be about 1.5 to about 3 times larger than the second area.

Each of the first bump electrode BP1-1 and the second bump electrode BP2-1 includes a plurality of protruding members PP. The first bump electrode BP1-1 may include a plurality of first protruding members PP1, and the second bump electrode BP2-1 may include a plurality of second protruding members PP2.

In an embodiment of the present disclosure, the numbers of the protruding members PP included in the first bump electrode BP1-1 and the second bump electrode BP2-1 may be different from each other. The number of the first protruding members PP1 included in the first bump electrode BP1-1 may be greater than the number of the second protruding members PP2 included in the second bump electrode BP2-1. However, the present disclosure is not limited thereto. For example, the number of the first protruding members PP1 included in the first bump electrode BP1-1 having a large planar area may be less than the number of the second protruding members PP2 included in the second bump electrode BP2-1 having a small planar area. As an example, FIGS. 8, 9A, and 9B illustrate that the first bump electrode BP1-1 includes six first protruding members PP1 and the second bump electrode BP2-1 includes two second protruding members PP2 which are less than the number of the first protruding members. However, the present disclosure is not limited thereto. For example, the number of the protruding patterns included in each of the first bump electrode BP1-1 and the second bump electrode BP2-1 may vary depending on the area of the bump, the contact area, and the like.

The protruding members PP included in each of the first bump electrode BP1-1 and the second bump electrode BP2-1 may have a circular shape on a plane, and the widths of the protruding members PP may be substantially the same as each other. The first protruding member PP1 included in the first bump electrode BP1-1 has a first pattern width d1, and the second protruding member PP2 included in the second bump electrode BP2-1 has a second pattern width d2, and the first pattern width d1 and the second pattern width d2 may be substantially the same as each other. In this specification, the expression “the widths are substantially the same” includes not only a case in which the widths of patterns are physically the same as each other, but also a case in which there is a difference between them due to errors occurring in a process, despite having a same design.

Referring to FIGS. 8 and 9A to 9C together, the third bump electrode BP3-1 may have a planar area different from that of at least one of the first bump electrode BP1-1 and the second bump electrode BP2-1. For example, the third bump electrode BP3-1 may have a larger planar area than the second bump electrode BP2-1. The third bump electrode BP3-1 may have a third width w3 in the first direction DR1, a third length h3 in the second direction DR2, and a third area on a plane. In an embodiment of the present disclosure, the third length h3 may be greater than the second width w2. The third area may be greater than the second area. For example, the third area may be about 1.5 to about 3 times larger than the second area.

The third bump electrode BP3-1 may include a plurality of third protruding members PP3. In an embodiment of the present disclosure, the number of the protruding patterns included in the third bump electrode BP3-1 may be different from the number of the protruding patterns included in at least one of the first bump electrode BP1-1 and the second bump electrode BP2-1. The number of the third protruding members PP3 included in the third bump electrode BP3-1 may be greater than the number of the second protruding members PP2 included in the second bump electrode BP2-1. However, the present disclosure is not limited thereto. For example, the number of the third protruding members PP3 included in the third bump electrode BP3-1 having a large planar area may be less than the number of the second protruding members PP2 included in the second bump electrode BP2-1 having a small planar area. As an example, FIG. 9C illustrates that the third bump electrode BP3-1 includes six third protruding members PP3. However, the number of the protruding patterns included in the third bump electrode BP3-1 may vary depending on the area of the bump, the contact area, and the like.

The third protruding member PP3 included in the third bump electrode BP3-1 may have a third pattern width d3. The third pattern width d3 may be substantially the same as the first pattern width d1 and the second pattern width d2 that are described above.

Each of FIGS. 10A to 10C is a cross-sectional view of a portion of the display device according to an embodiment of the present disclosure. FIG. 10A illustrates a cross section of the display device DD corresponding to a line I-I′ illustrated in FIG. 9A. FIG. 10B illustrates a cross section of the display device DD corresponding to a line II-II′ illustrated in FIG. 9B. FIG. 10C illustrates a cross section of the display device DD corresponding to a line III-III′ illustrated in FIG. 9C.

Referring to FIGS. 9A to 9C and FIGS. 10A to 10C together, the display device DD according to an embodiment of the present disclosure may include a display panel DP and a driving unit DC, and the display panel DP and the driving unit DC may be bonded to each other by a first adhesive layer CF1. The first adhesive layer CF1 may include synthetic resin having adhesive properties. Each first adhesive layer CF1 may include a non-conductive film. Each first adhesive layer CF1 may not include conductive particles such as conductive balls and may include a curable polymer material.

The display panel DP includes a substrate SUB, a plurality of insulating layers BFL, INS1, INS2, INS3, and INS4 disposed on the substrate SUB, and pad electrodes PD1, PD2, and PD3. The pad electrodes PD1, PD2, and PD3 may be electrically connected to corresponding signal lines. In an embodiment of the present disclosure, a first pad electrode PD1 may be electrically connected to a connection signal line S-CL. A second pad electrode PD2 may be electrically connected to a data line DL. A third pad electrode PD3 may be electrically connected to an additional line ADL.

The driving unit DC may include a driving integrated circuit DC-B and bump electrodes BP1, BP2, and BP3 disposed below the driving integrated circuit DC-B. The bump electrodes BP1, BP2, and BP3 may include a plurality of protruding members PP1, PP2, and PP3 and bonding layers CM1, CM2, and CM3.

The driving unit DC may further include driving pads DC-P1, DC-P2, and DC-P3 disposed below the driving integrated circuit DC-B and a driving insulating layer DC-I that exposes a portion of the lower surface of the driving pads DC-P1, DC-P2, and DC-P3 and covers the remaining portions of the lower surface of the driving pads DC-P1, DC-P2, and DC-P3. The driving pads DC-P1, DC-P2, and DC-P3 may be disposed on the lower surface DC-DS of the driving integrated circuit DC-B. The driving pads DC-P1, DC-P2, and DC-P3 are electrically connected to the bump electrodes BP1, BP2, and BP3 so that they may transmit signals provided from the driving integrated circuit DC-B to the bump electrodes BP1, BP2, and BP3 or transmit signals provided from the bump electrodes BP1, BP2, and BP3 to the driving integrated circuit DC-B. The driving pads DC-P1, DC-P2, and DC-P3 may include a first driving pad DC-P1 to which a first bump electrode BP1 is electrically connected, a second driving pad DC-P2 to which a second bump electrode BP2 is electrically connected, and a third driving pad DC-P3 to which a third bump electrode BP3 is electrically connected.

The driving insulating layer DC-I may include an insulating material. The driving insulating layer DC-I may be an inorganic layer or an organic layer.

The plurality of protruding members PP1, PP2, and PP3 included in the bump electrodes BP1, BP2, and BP3 may protrude from the lower surface DC-DS of the driving integrated circuit DC-B toward a direction adjacent to the display panel DP. The plurality of protruding members PP1, PP2, and PP3 may include a polymer material. The plurality of protruding members PP1, PP2, and PP3 may include, for example, polyimide.

Each of the plurality of protruding members PP1, PP2, and PP3 may have a circular shape on a plane, and the widths of the plurality of protruding members PP1, PP2, and PP3 in one direction may be substantially the same as each other. That is, the first pattern width d1 of the first protruding member PP1, the second pattern width d2 of the second protruding member PP2, and the third pattern width d3 of the third protruding member PP3 may be substantially the same as each other. Each of the plurality of protruding members PP1, PP2, and PP3 may have a shape with a width that decreases as it approaches the display panel DP. As illustrated in FIGS. 10A to 10C, each of the plurality of protruding members PP1, PP2, and PP3 may have a cylindrical shape with a rounded lower surface provided adjacent to the display panel DP so that the width of each of the plurality of protruding members PP1, PP2, and PP3 decreases as it approaches the display panel DP. However, the present disclosure is not limited thereto. For example, each of the plurality of protruding members PP1, PP2, and PP3 may have a conical shape with a width that decreases as it approaches the display panel DP.

The plurality of protruding members PP1, PP2, and PP3 in the bump electrodes BP1, BP2, and BP3 may be arranged side by side along one direction. For example, the plurality of first protruding members PP1 in each of the first bump electrodes BP1 may be arranged side by side in the second direction DR2. For example, the plurality of first protruding members PP1 in each of the first bump electrodes BP1 may be arranged side by side in the first direction DR1. for example, the plurality of second protruding members PP2 in each of the second bump electrodes BP2 may be arranged side by side in the second direction DR2. for example, the plurality of third protruding members PP3 in each of the third bump electrodes BP3 may be arranged side by side in each of the first direction DR1 and the second direction DR2.

The bonding layers CM1, CM2, and CM3 included in the bump electrodes BP1, BP2, and BP3 are respectively disposed below and cover the plurality of protruding members PP1, PP2, and PP3. The first bump electrode BP1 may include a first bonding layer CM1 covering the first protruding member PP1, the second bump electrode BP2 may include a second bonding layer CM2 covering the second protruding member PP2, and the third bump electrode BP3 may include a third bonding layer CM3 covering the third protruding member PP3.

The bonding layers CM1, CM2, and CM3 may include a conductive metal. The bonding layers CM1, CM2, and CM3 may include, for example, any one selected from gold (Au), copper (Cu), tin (Sn), a gold-tin alloy (Au/Sn), a tin-silver alloy (Sn/Ag), indium (In), a bismuth-tin alloy (Bi/Sn), and a tin-lead alloy (Sn/Pb).

In the display device DD according to an embodiment of the present disclosure, the bonding layer CM1, CM2, or CM3 is in contact with the corresponding pad electrode PD1, PD2, or PD3. The first bonding layer CM1 included in the first bump electrode BP1 may be in contact with the first pad electrode PD1, the second bonding layer CM2 included in the second bump electrode BP2 may be in contact with the second pad electrode PD2, and the third bonding layer CM3 included in the third bump electrode BP3 may be in contact with the third pad electrode PD3.

The bump electrodes BP1, BP2, and BP3 may further include intermediate layers UM1, UM2, and UM3. The intermediate layers UM1, UM2, and UM3 may be disposed between the protruding members PP1, PP2, and PP3 and the bonding layers CM1, CM2, and CM3. The intermediate layers UM1, UM2, and UM3 may cover the outer surfaces of the plurality of protruding members PP1, PP2, and PP3. The intermediate layers UM1, UM2, and UM3 may be electrically connected to the driving pads DC-P1, DC-P2, and DC-P3 of the driving unit DC. The intermediate layers UM1, UM2, and UM3 may include a first intermediate layer UM1 connected to the first driving pad DC-P1 and disposed between the first protruding member PP1 and the first bonding layer CM1, a second intermediate layer UM2 connected to the second driving pad DC-P2 and disposed between the second protruding member PP2 and the second bonding layer CM2, and a third intermediate layer UM3 connected to the third driving pad DC-P3 and disposed between the third protruding member PP3 and the third bonding layer CM3. The intermediate layers UM1, UM2, and UM3 may include a conductive metal. The intermediate layers UM1, UM2, and UM3 may include, for example, any one selected from titanium (Ti), titanium-tungsten (TiW), copper (Cu), nickel (Ni), gold (Au), and nickel-vanadium (NiV).

In the display device DD according to an embodiment of the present disclosure, contact areas in which the bonding layers CM1 and CM2 included in the first bump electrode BP1 and the second bump electrode BP2 are respectively in contact with corresponding pad electrodes PD1 and PD2 may be different from each other. The first bonding layer CM1 included in the first bump electrode BP1 may be in contact with a corresponding first pad electrode PD1, and an area in which the first bonding layer CM1 is in contact with the corresponding first pad electrode PD1 may be referred to as a first contact area CA1. The second bonding layer CM2 included in the second bump electrode BP2 may be in contact with a corresponding second pad electrode PD2, and an area in which the second bonding layer CM2 is in contact with the corresponding second pad electrode PD2 may be referred to as a second contact area CA2. In the display device DD according to an embodiment of the present disclosure, the first contact area CA1 is larger than the second contact area CA2. In the driving unit DC according to an embodiment of the present disclosure, the widths d1 and d2 of the protruding members PP1 and PP2 respectively included in the first bump electrode BP1 and the second bump electrode BP2 may be substantially the same as each other, but since the number of the first protruding members PP1 included in the first bump electrode BP1 is greater than the number of the second protruding members PP2 included in the second bump electrode BP2, the first contact area CA1 may be larger than the second contact area CA2.

In the display device DD according to an embodiment of the present disclosure, the third bonding layer CM3 included in the third bump electrode BP3 may be in contact with a corresponding third pad electrode PD3, and an area in which the third bonding layer CM3 is in contact with the corresponding third pad electrode PD3 may be referred to as a third contact area CA3. In the display device DD according to an embodiment of the present disclosure, the third contact area CA3 may be larger than the second contact area CA2. In the driving unit DC according to an embodiment of the present disclosure, the widths d2 and d3 of the protruding members PP2 and PP3 respectively included in the second bump electrode BP2 and the third bump electrode BP3 may be substantially the same as each other, but since the number of the third protruding members PP3 included in the third bump electrode BP3 is greater than the number of the second protruding members PP2 included in the second bump electrode BP2, the third contact area CA3 may be larger than the second contact area CA2.

Referring to FIG. 8 again, the driving unit DC may be divided into an upper portion and a lower portion with respect to a center line HL extending along the first direction DR1. The center line HL may extend along the first direction DR1 and cross the central portion of the driving unit DC along the second direction DR2. The first bump electrodes BP1 may be disposed on the upper portion, and the second bump electrodes BP2 may be disposed on the lower portion. Upper third bump electrodes BP3-S1 among the third bump electrodes BP3 may be disposed on the upper portion, and lower third bump electrodes BP3-S2 among the third bump electrodes BP3 may be disposed on the lower portion. In an embodiment of the present disclosure, the number of the lower third bump electrodes BP3-S2 disposed on the lower portion of the driving unit DC and the number of the upper third bump electrodes BP3-S1 disposed on the upper portion of the driving unit DC may be the same as each other.

Referring to FIGS. 8 to 10C together, in the driving unit DC according to an embodiment of the present disclosure, the total planar area of the protruding members included in the bump electrodes disposed on the upper portion may be between about 75% and about 120% of the total planar area of the protruding members included in the bump electrodes disposed on the lower portion. For example, the total planar area of the protruding members included in the bump electrodes disposed on the upper portion of the driving unit DC may be between about 90% and about 105% of the total planar area of the protruding members included in the bump electrodes disposed on the lower portion of the driving unit DC.

In an embodiment of the present disclosure, the number of the second bump electrodes BP2 included in the driving unit DC may be greater than the number of the first bump electrodes BP1 included in the driving unit DC, but since the number of the first protruding members PP1 included in each of the first bump electrodes BP1 is greater than the number of the second protruding members PP2 included in each of the second bump electrodes BP2, the total planar area of the protruding members included in the bump electrodes disposed on the upper portion may be between about 75% and about 120% of the total planar area of the protruding members included in the bump electrodes disposed on the lower portion.

Unlike the embodiment of the present disclosure, when the number of the first protruding members PP1 included in each of the first bump electrodes BP1 and the number of the second protruding members PP2 included in each of the second bump electrodes BP2 are the same as each other, the total planar area of the protruding members included in the bump electrodes disposed on the upper portion may be less than about 50% of the total planar area of the protruding members included in the bump electrodes disposed on the lower portion because the number of the second bump electrodes BP2 included in the driving unit DC is greater than the number of the first bump electrodes BP1 included in the driving unit DC. Therefore, in a process of pressing the display panel and the driving unit, pressure applied to the upper portion and the lower portion may become uneven, and defects may occur in the electrical connection between the bump electrodes and the pad electrodes. In the driving unit DC according to an embodiment of the present disclosure, by designing the number of the first protruding members PP1 included in each of the first bump electrodes BP1 to be greater than the number of the second protruding members PP2 included in each of the second bump electrodes BP2, it is possible to adjust the total planar area of the protruding members included in the bump electrodes disposed on the upper portion to be between about 75% and about 120% of the total planar area of the protruding members included in the bump electrodes disposed on the lower portion.

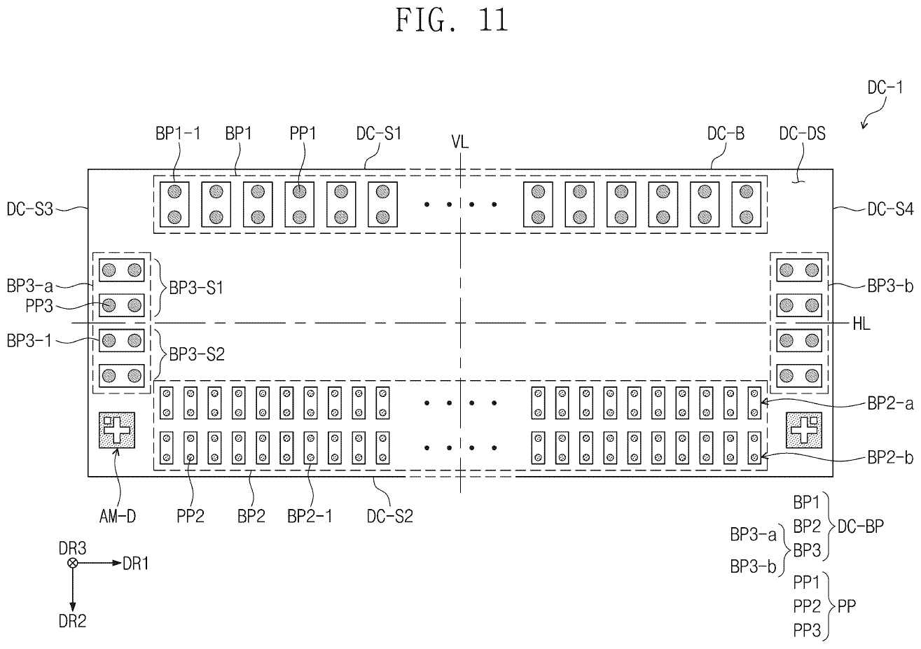

FIG. 11 is a plan view of a driving unit according to an embodiment of the present disclosure. FIG. 11 illustrates a driving unit DC-1, which is different from the driving unit DC described in FIG. 8. The same reference numerals will be given to the same components as those described in FIGS. 8 to 10C, and the detailed descriptions thereof will be omitted.

Referring to FIG. 7 and FIG. 11, the driving unit DC may include a driving integrated circuit DC-B and a plurality of bump electrodes DC-BP disposed on the lower surface DC-DS of the driving integrated circuit DC-B. The bump electrodes DC-BP include a plurality of first bump electrodes BP1 and a plurality of second bump electrodes BP2. Each of the first bump electrodes BP1 may have a larger planar area than each of the second bump electrodes BP2. Each of the first bump electrodes BP1 may have a rectangular shape having a larger planar area than each of the second bump electrodes BP2.

The numbers of the plurality of first bump electrodes BP1 and the plurality of second bump electrodes BP2 included in the driving unit DC may be different from each other. In the driving unit DC according to an embodiment of the present disclosure, the number of the first bump electrodes BP1 may be smaller than that of the second bump electrodes BP2. The number of the plurality of second bump electrodes BP2 included in the driving unit DC may be greater than the number of the plurality of first bump electrodes BP1 and the number of the plurality of third bump electrodes BP3.

Each of the bump electrodes DC-BP may include a plurality of protruding members PP. Each of the plurality of protruding members PP may have a shape that protrudes so as to be adjacent to the display panel DP. That is, each of the plurality of protruding members PP may have a shape that protrudes in a direction opposite to the third direction DR3.

In the driving unit DC according to an embodiment of the present disclosure, the plurality of first protruding members PP1 included in each of the first bump electrodes BP1 and the plurality of second protruding members PP2 included in each of the second bump electrodes BP2 differ in their planar area. Accordingly, in the display device including the driving unit DC according to an embodiment, areas in which each of the first bump electrodes BP1 and each of the second bump electrodes BP2 are in contact with corresponding pad electrodes may be different from each other. The third bump electrodes BP3 may include a plurality of third protruding members PP3, and the third protruding members PP3 may differ from either the plurality of first protruding members PP1 or the plurality of second protruding members PP2 in their planar areas.

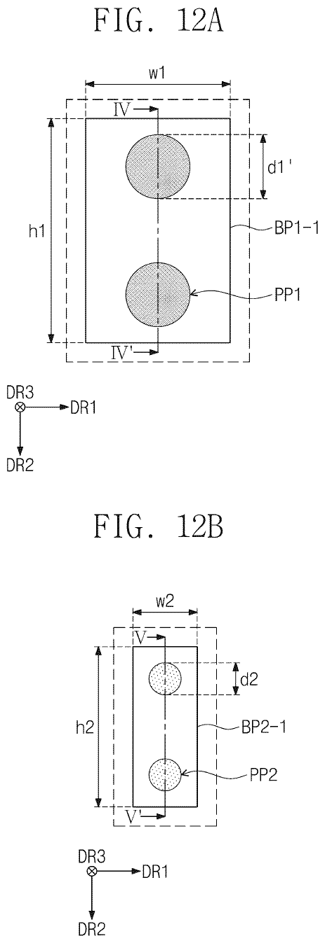

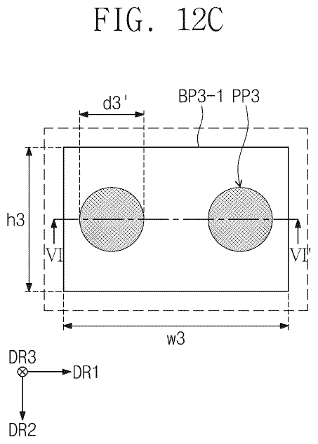

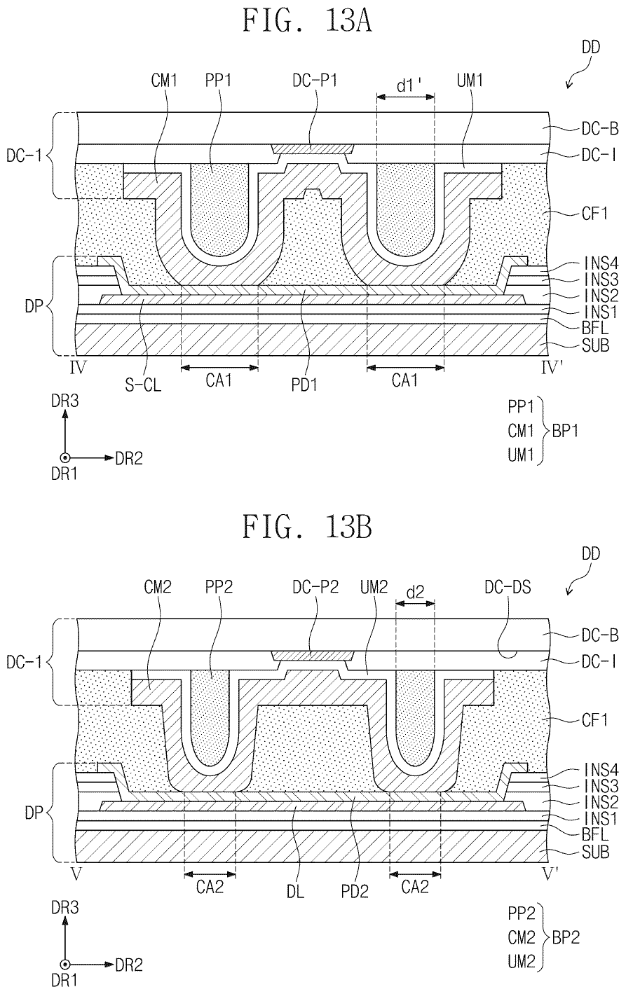

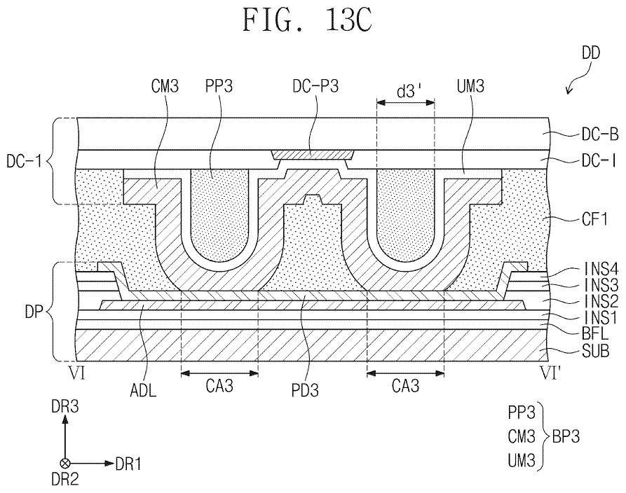

FIG. 12A is a plan view of one of the first bump electrodes included in the driving unit according to an embodiment of the present disclosure. FIG. 12B is a plan view of one of the second bump electrodes included in the driving unit according to an embodiment of the present disclosure. FIG. 12C is a plan view of one of the third bump electrodes included in the driving unit according to an embodiment of the present disclosure. FIG. 12A illustrates an enlarged view of one of the first bump electrodes BP1-1 among the plurality of first bump electrodes BP1 illustrated in FIG. 11, FIG. 12B illustrates an enlarged view of one of the second bump electrodes BP2-1 among the plurality of second bump electrodes BP2 illustrated in FIG. 11, and FIG. 12C illustrates an enlarged view of one of the third bump electrodes BP3 illustrated in FIG. 11.

Referring to FIGS. 11, 12A, and 12B together, the first bump electrode BP1-1 may have a larger planar area than the second bump electrode BP2-1. The first bump electrode BP1-1 may have a first width w1 in the first direction DR1, a first length h1 in the second direction DR2, and a first area on a plane. The second bump electrode BP2-1 may have a second width w2 in the first direction DR1, a second length h2 in the second direction DR2, and a second area on a plane. In an embodiment of the present disclosure, the first width w1 may be greater than the second width w2. The first area may be larger than the second area. For example, the first area may be about 1.5 to about 3 times larger than the second area.

Each of the first bump electrode BP1-1 and the second bump electrode BP2-1 includes a plurality of protruding members PP. The first bump electrode BP1-1 may include a plurality of first protruding members PP1, and the second bump electrode BP2-1 may include a plurality of second protruding members PP2.

In an embodiment of the present disclosure, the planar areas of the protruding members PP respectively included in the first bump electrode BP1-1 and the second bump electrode BP2-1 may be different from each other. The protruding members PP respectively included in the first bump electrode BP1-1 and the second bump electrode BP2-1 may have a circular shape on a plane, and the widths of the protruding members PP having the circular shape may be different from each other. The first protruding member PP1 included in the first bump electrode BP1-1 may have a first pattern width d1′, the second protruding member PP2 included in the second bump electrode BP2-1 may have a second pattern width d2, and the first pattern width d1′ may be larger than the second pattern width d2.

In an embodiment of the present disclosure, the numbers of the protruding members PP respectively included in the first bump electrode BP1-1 and the second bump electrode BP2-1 may be the same as each other. The number of the first protruding members PP1 included in the first bump electrode BP1-1 may be the same as the number of the second protruding members PP2 included in the second bump electrode BP2-1. As an example, FIGS. 11, 12A, and 12B illustrate that the first bump electrode BP1-1 includes two first protruding members PP1 and the second bump electrode BP2-1 includes two second protruding members PP2 which is the same number as the first protruding members PP1. However, the numbers of the protruding patterns respectively included in the first bump electrode BP1-1 and the second bump electrode BP2-1 may vary depending on the area of the bump, the contact area, and the like.

Referring to FIG. 11 and FIGS. 12A to 12C together, the third bump electrode BP3-1 may have a planar area different from that of at least one of the first bump electrode BP1-1 and the second bump electrode BP2-1. For example, the third bump electrode BP3-1 may have a larger planar area than the second bump electrode BP2-1. The third bump electrode BP3-1 may have a third width w3 in the first direction DR1, a third length h3 in the second direction DR2, and a third area on a plane. In an embodiment of the present disclosure, the third length h3 may be greater than the second width w2. The third area may be greater than the second area. For example, the third area may be about 1.5 to about 3 times larger than the second area.

The third bump electrode BP3-1 may include a plurality of third protruding members PP3. In an embodiment of the present disclosure, the protruding pattern included in the third bump electrode BP3-1 may have a circular shape on a plane and may have a planar area different from that of the protruding pattern included in at least any one of the first bump electrode BP1-1 and the second bump electrode BP2-1. For example, the third protruding member PP3 included in the third bump electrode BP3-1 may have a third pattern width d3′. The third pattern width d3′ may be larger than the second pattern width d2 described above.

In an embodiment of the present disclosure, the number of the protruding members PP included in the third bump electrode BP3-1 may be the same as the number of the protruding members PP included in each of the first bump electrode BP1-1 and the second bump electrode BP2-1. The number of the third protruding members PP3 included in the third bump electrode BP3-1 may be the same as the number of the first protruding members PP1 included in the first bump electrode BP1-1 and the number of the second protruding members PP2 included in the second bump electrode BP2-1. As an example, FIGS. 11 and 12A to 12C illustrate that the first bump electrode BP1-1 includes two first protruding members PP1, the second bump electrode BP2-1 includes two second protruding members PP2, and the third bump electrode BP3-1 also includes two third protruding members PP3. However, the number of the protruding patterns included in each of the first bump electrodes BP1-1 to the third bump electrodes BP3-1 may vary depending on the area of the bump, the contact area, and the like.

Each of FIGS. 13A to 13C is a cross-sectional view of a portion of the display device according to an embodiment of the present disclosure. FIG. 13A illustrates a cross section of the display device DD corresponding to a line IV-IV′ illustrated in FIG. 12A. FIG. 13B illustrates a cross section of the display device DD corresponding to a line V-V′ illustrated in FIG. 12B. FIG. 13C illustrates a cross section of the display device DD corresponding to a line VI-VI′ illustrated in FIG. 12C.

Referring to FIGS. 12A to 12C and FIGS. 13A to 13C together, the display device DD according to an embodiment of the present disclosure may include a display panel DP and a driving unit DC-1, and the display panel DP and the driving unit DC-1 may be bonded to each other by a first adhesive layer CF1.

The display panel DP includes a substrate SUB, a plurality of insulating layers BFL, INS1, INS2, INS3, and INS4 disposed on the substrate SUB, and pad electrodes PD1, PD2, and PD3. The pad electrodes PD1, PD2, and PD3 may be electrically connected to corresponding signal lines. In an embodiment of the present disclosure, a first pad electrode PD1 may be electrically connected to a connection signal line S-CL. A second pad electrode PD2 may be electrically connected to a data line DL. A third pad electrode PD3 may be electrically connected to an additional line ADL.

The driving unit DC-1 includes a driving integrated circuit DC-B and bump electrodes BP1, BP2, and BP3 disposed below the driving integrated circuit DC-B. The bump electrodes BP1, BP2, and BP3 include a plurality of protruding members PP1, PP2, and PP3 and bonding layers CM1, CM2, and CM3.

The plurality of protruding members PP1, PP2, and PP3 included in the bump electrodes BP1, BP2, and BP3 may protrude from the lower surface DC-DS of the driving integrated circuit DC-B toward a direction adjacent to the display panel DP. The plurality of protruding members PP1, PP2, and PP3 may include a polymer material. The plurality of protruding members PP1, PP2, and PP3 may include, for example, polyimide.

The bonding layers CM1, CM2, and CM3 included in the bump electrodes BP1, BP2, and BP3 are respectively disposed below and cover the plurality of protruding members PP1, PP2, and PP3.

The bump electrodes BP1, BP2, and BP3 may further include intermediate layers UM1, UM2, and UM3. The intermediate layers UM1, UM2, and UM3 may be disposed between the protruding members PP1, PP2, and PP3 and the bonding layers CM1, CM2, and CM3. The intermediate layers UM1, UM2, and UM3 may respectively cover the outer surfaces of the plurality of protruding members PP1, PP2, and PP3. The intermediate layers UM1, UM2, and UM3 may be electrically connected to the driving pads DC-P1, DC-P2, and DC-P3 of the driving unit DC-1.

In the display device DD according to an embodiment of the present disclosure, the bonding layer CM1, CM2, or CM3 is in contact with one corresponding pad electrode PD1, PD2, or PD3. A first bonding layer CM1 included in the first bump electrode BP1 may be in contact with the first pad electrode PD1, a second bonding layer CM2 included in the second bump electrode BP2 may be in contact with the second pad electrode PD2, and a third bonding layer CM3 included in the third bump electrode BP3 may be in contact with the third pad electrode PD3.

In the display device DD according to an embodiment of the present disclosure, contact areas in which the bonding layers CM1 and CM2 included in the first bump electrode BP1 and the second bump electrode BP2 are respectively in contact with corresponding pad electrodes PD1 and PD2 may be different from each other. The first bonding layer CM1 included in the first bump electrode BP1 may be in contact with a corresponding first pad electrode PD1, and an area in which the first bonding layer CM1 is in contact with the corresponding first pad electrode PD1 may be referred to as a first contact area CA1. The second bonding layer CM2 included in the second bump electrode BP2 is in contact with a corresponding second pad electrode PD2, and an area in which the second bonding layer CM2 is in contact with the corresponding second pad electrode PD2 may be referred to as a second contact area CA2. In the display device DD according to an embodiment of the present disclosure, the first contact area CA1 is larger than the second contact area CA2.

In the display device DD according to an embodiment of the present disclosure, since the first pattern width d1′ of the first protruding member PP1 and the second pattern width d2 of the second protruding member PP2 are different from each other, the first contact area CA1 and the second contact area CA2 may be different from each other. Since the first pattern width d1′ of the first protruding member PP1 is greater than the second pattern width d2 of the second protruding member PP2, the first contact area CA1 may also be larger than the second contact area CA2. In the driving unit DC-1 according to an embodiment of the present disclosure, the numbers of the protruding members PP1 and PP2 respectively included in the first bump electrode BP1 and the second bump electrode BP2 are the same as each other, but since the pattern widths of the protruding members PP1 and PP2 are different from each other, the first contact area CA1 may be larger than the second contact area CA2.

In the display device DD according to an embodiment of the present disclosure, the third bonding layer CM3 included in the third bump electrode BP3 may be in contact with a corresponding third pad electrode PD3, and an area in which the third bonding layer CM3 is in contact with the corresponding third pad electrode PD3 may be referred to as a third contact area CA3. In the display device DD according to an embodiment of the present disclosure, the third contact area CA3 may be larger than the second contact area CA2. In the driving unit DC-1 according to an embodiment of the present disclosure, the numbers of the protruding members PP2 and PP3 respectively included in the second bump electrode BP2 and the third bump electrode BP3 may be substantially the same as each other, but since the third pattern width d3′ of the third protruding member PP3 included in the third bump electrode BP3 is greater than the second pattern width d2 of the second protruding member PP2 included in the second bump electrode BP2, the third contact area CA3 may also be larger than the second contact area CA2.

Referring to FIG. 11 again, the driving unit DC-1 may be divided into an upper portion and a lower portion with respect to the center line HL extending along the first direction DR1. The center line HL may extend along the first direction DR1 and cross the central portion of the driving unit DC-1 along the second direction DR2. The first bump electrodes BP1 may be disposed on the upper portion, and the second bump electrodes BP2 may be disposed on the lower portion. Upper third bump electrodes BP3-S1 among the third bump electrodes BP3 may be disposed on the upper portion, and lower third bump electrodes BP3-S2 among the third bump electrodes BP3 may be disposed on the lower portion. In an embodiment of the present disclosure, the number of the lower third bump electrodes BP3-S2 disposed on the lower portion of the driving unit DC-1 and the number of the upper third bump electrodes BP3-S1 disposed on the upper portion of the driving unit DC-1 may be the same as each other.

Referring to FIGS. 11 to 13C together, in the driving unit DC-1 according to an embodiment of the present disclosure, the total planar area of the protruding members included in the bump electrodes disposed on the upper portion may be between about 75% and about 120% of the total planar area of the protruding members included in the bump electrodes disposed on the lower portion. For example, in the driving unit DC-1, the total planar area of the protruding members included in the bump electrodes disposed on the upper portion may be between about 90% and about 105% of the total planar area of the protruding members included in the bump electrodes disposed on the lower portion.

In an embodiment of the present disclosure, the number of the second bump electrodes BP2 included in the driving unit DC-1 may be greater than the number of the first bump electrodes BP1 included in the driving unit DC-1, but since the planar area of each of the first protruding members PP1 included in each of the first bump electrodes BP1 is greater than the planar area of each of the second protruding members PP2 included in each of the second bump electrodes BP2, the total planar area of the protruding members included in the bump electrodes disposed on the upper portion may be between about 75% and about 120% of the total planar area of the protruding members included in the bump electrodes disposed on the lower portion.

Unlike the embodiment of the present disclosure, when the planar area of each of the first protruding members PP1 included in each of the first bump electrodes BP1 and the planar area of each of the second protruding members PP2 included in each of the second bump electrodes BP2 are the same as each other, the total planar area of the protruding members included in the bump electrodes disposed on the upper portion may be less than about 50% of the total planar area of the protruding members included in the bump electrodes disposed on the lower portion because the number of the second bump electrodes BP2 included in the driving unit DC-1 is greater than the number of the first bump electrodes BP1 included in the driving unit DC-1. Therefore, in a process of pressing the display panel and the driving unit, pressure applied to the upper portion and the lower portion may become uneven, and defects may occur in the electrical connection between the bump electrodes and the pad electrodes. In the driving unit DC-1 according to an embodiment of the present disclosure, by designing the planar area of each of the first protruding members PP1 included in each of the first bump electrodes BP1 to be larger than the planar area of each of the second protruding members PP2 included in each of the second bump electrodes BP2, it is possible to adjust the total planar area of the protruding members included in the bump electrodes disposed on the upper portion to be between about 75% and about 120% of the total planar area of the protruding members included in the bump electrodes disposed on the lower portion.

In the display device DD according to an embodiment of the present disclosure, the bump electrodes BP1, BP2, and BP3 included in the driving units DC and DC-1 include protruding members PP1, PP2, and PP3 and bonding layers CM1, CM2, and CM3, and the bonding layers CM1, CM2, and CM3 are in direct contact with corresponding pad electrodes PD1, PD2, and PD3. Accordingly, even though the first adhesive layer CF1 bonding the display panel DP to the driving unit DC or DC-1 does not include separate conductive particles such as conductive balls, the bump electrodes BP1, BP2, and BP3 of the driving unit DC or DC-1 and the pad electrodes PD1, PD2, and PD3 of the display panel DP may be electrically connected to each other. Accordingly, even though the display panel DP and the driving unit DC or DC-1 are misaligned with each other, a short circuit due to conductive particles such as conductive balls does not occur, and thus, the electrical connection characteristics between the pad electrode and the bump electrode may be improved.

According to an embodiment, at least some of the bump electrodes BP1, BP2, and BP3 included in the driving unit DC or DC-1 may have a planar area different from that of the remaining ones. For example, the first bump electrodes BP1 may have a larger planar area than the second bump electrodes BP2. A greater pressure may be applied to each of the first bump electrodes BP1 having a relatively larger planar area during a pressing process, and a smaller pressure may be applied to each of the second bump electrodes BP2 having a relatively smaller planar area during a pressing process. Unlike the display device according to the embodiment of the present disclosure, when the numbers and planar areas of protruding members respectively provided to the first bump electrodes BP1 and the second bump electrodes BP2, which have different planar areas, are the same as each other, the electrical connection characteristics with the pad electrodes may also vary, due to the difference in pressure applied between the first bump electrodes BP1 and the second bump electrodes BP2 in a process of pressing the display panel DP and the driving unit DC or DC-1.

In the display device according to an embodiment of the present disclosure, by making the numbers or planar areas of the plurality of first protruding members PP1 included in each of the first bump electrodes BP1 and the plurality of second protruding members PP2 included in each of the second bump electrodes BP2 different from each other, it is possible to increase a contact area between each of the first bump electrodes BP1 having a larger planar area than the second bump electrode BP2 and a corresponding first pad electrode PD1 in contact with the first bump electrodes BP1. That is, since the number of the plurality of first protruding members PP1 included in each of the first bump electrodes BP1 is greater than the number of the plurality of second protruding members PP2 included in each of the second bump electrodes BP2, or the planar area of an individual protruding pattern is larger, the first contact area CA1 between each of the first bump electrodes BP1 and a corresponding first pad electrode PD1 may be larger than the second contact area CA2 between each of the second bump electrodes BP2 and a corresponding second pad electrode PD2. Accordingly, in a process of pressing the display panel DP and the driving unit DC or DC-1, pressure between the bump electrodes and the pad electrodes may be uniformly transmitted, resulting in a uniform adjustment of the electrical connection characteristics between the bump electrodes and the pad electrodes. Accordingly, the reliability of the display device including the driving unit may be improved.

The display device according to the embodiment can be applied to various electronic devices. The electronic device according to one embodiment includes the display device described above, and may further include modules or devices having additional functions in addition to the display device.

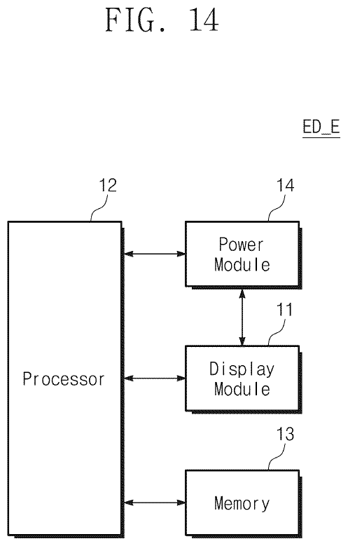

FIG. 14 is a block diagram of an electronic device according to one embodiment. Referring to FIG. 14, the electronic device ED_E according to one embodiment may include a display module 11, a processor 12, a memory 13, and a power module 14. The display module 11 may include the display panel DP as described in FIG. 4.

The processor 12 may include at least one of a central processing unit CPU, an application processor AP, a graphic processing unit GPU, a communication processor CP, an image signal processor ISP, and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as a power adapter or a battery device, and a power conversion module that converts the power supplied by the power supply module to generate power necessary for the operation of the electronic device ED_E.

At least one of the components of the electronic device ED_E described above may be included in the display device according to the embodiments described above. In addition, some of the individual modules functionally included in one module may be included in the display device, and other parts may be provided separately from the display device. For example, the display device may include the display module 11, and the processor 12, the memory 13, and the power module 14 may be provided in the form of other devices within the electronic device ED_E other than the display device.

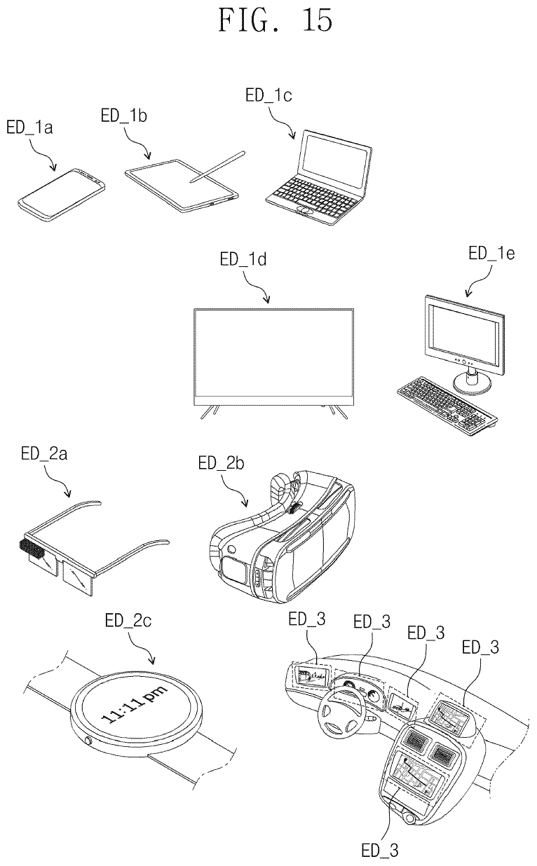

FIG. 15 is a schematic diagram of an electronic device according to various embodiments. Referring to FIG. 15, various electronic devices to which display devices according to embodiments are applied may include not only image display electronic devices such as a smart phone ED_1a, a tablet PC ED_1b, a laptop ED_1c, a TV ED_1d, and a desk monitor ED_1e, but also wearable electronic devices including display modules such as smart glasses ED_2a, a head mounted display ED_2b, and a smart watch ED_2c, and vehicle electronic devices ED_3 including display modules such as a CID (Center Information Display) and a room mirror display arranged on a dashboard, center fascia, and dashboard of an automobile.

In a display device according to an embodiment of the present disclosure, by making the numbers or planar areas of protruding members respectively included in a plurality of bump electrodes included in a driving unit different from each other, a contact area between each of the bump electrodes and a corresponding pad electrode may be adjusted differently. Accordingly, even though some of the plurality of bump electrodes have a planar area different from that of the remaining ones, pressure between the bump electrodes and the pad electrodes may be uniformly transmitted in a process of pressing the display panel and the driving unit, resulting in a uniform adjustment of the electrical connection characteristics between the bump electrodes and the pad electrodes. Accordingly, the reliability of the display device including the driving unit may be improved.

Although the above has been described with reference to an embodiment of the present disclosure, those skilled in the art will understand that various modifications and changes can be made to the inventive concept without departing from the scope and the spirit of the present disclosure as set forth in the following claims.

Accordingly. it is understood that the technical scope of the present disclosure should not be limited to the content described in the detailed description of the specification, but should be determined by the claims described hereinafter.

What is claimed is:

1. A display device comprising:
a display panel comprising a display region in which pixels are disposed and a non-display region in which a plurality of pad electrodes are disposed; and
a driving unit disposed on the display panel and comprising a plurality of bump electrodes, each of the plurality of bump electrodes connecting to a corresponding pad electrode among the plurality of pad electrodes,
wherein the plurality of bump electrodes comprise:
a plurality of first bump electrodes arranged along a first direction; and
a plurality of second bump electrodes spaced apart from the plurality of first bump electrodes along a second direction crossing the first direction, and arranged along the first direction,
wherein each of the plurality of first bump electrodes and the plurality of second bump electrodes comprises:
a plurality of protruding members protruding to be adjacent to the display panel; and
a bonding layer covering the plurality of protruding members and including a metal, the bonding layer of each of the plurality of first bump electrodes partially in contact with a first pad electrode among the plurality of pad electrodes and the bonding layer of each of the plurality of second bump electrodes partially in contact with a second pad electrode among the plurality of pad electrodes,
wherein a first area of each of the plurality of first bump electrodes is larger than a second area of each of the plurality of second bump electrodes, and
wherein a first contact area between the bonding layer of each of the plurality of first bump electrodes and the first pad electrode is larger than a second contact area between the bonding layer of each of the plurality of the second bump electrodes and the second pad electrode.

2. The display device of claim 1, further comprising:
a first adhesive layer disposed between the display panel and the driving unit and bonding the display panel to the driving unit,
wherein the first adhesive layer comprises a non-conductive film.

3. The display device of claim 1, wherein the driving unit further comprises:
a driving integrated circuit; and
a driving pad disposed below a lower surface of the driving integrated circuit, and
wherein the plurality of bump electrodes are disposed below the lower surface of the driving integrated circuit.

4. The display device of claim 3, wherein each of the plurality of first bump electrodes and the plurality of second bump electrodes further comprises an intermediate layer disposed between the plurality of protruding members and the bonding layer and electrically connected to the driving pad.

5. The display device of claim 1,
wherein the first pad electrode overlaps each of the plurality of first bump electrodes on a plane, and the second pad electrode overlaps each of the plurality of second bump electrodes on the plane.

6. The display device of claim 5, wherein a planar area of each of the plurality of protruding members in each of the plurality of first bump electrodes is larger than a planar area of each of the plurality of protruding members in each of the plurality of second bump electrodes.

7. The display device of claim 5, wherein the number of the plurality of protruding members in each of the plurality of first bump electrodes is greater than the number of the plurality of protruding members in each of the plurality of second bump electrodes.

8. The display device of claim 5,
wherein each of the plurality of protruding members in each of the plurality of first bump electrodes is arranged side by side in the second direction, and
wherein each of the plurality of protruding members in each of the plurality of second bump electrodes is arranged side by side in the second direction.

9. The display device of claim 1,
wherein the driving unit comprises:
a first long side extending in the first direction;
a second long side extending in the first direction and spaced apart from the first long side along the second direction;
a first short side extending in the second direction and connecting the first long side and the second long side to each other; and
a second short side extending in the second direction and spaced apart from the first short side along the first direction, and
wherein the plurality of first bump electrode are disposed adjacent to the first long side, and the plurality of second bump electrodes are disposed adjacent to the second long side.

10. The display device of claim 9, wherein the plurality of bump electrodes further comprise a plurality of third bump electrodes disposed adjacent to at least one of the first short side and the second short side and arranged along the second direction.

11. The display device of claim 10, wherein a third area of each of the plurality of third bump electrodes is larger than the second area.

12. The display device of claim 10,
wherein each of the plurality of third bump electrodes comprise:
a plurality of third protruding members protruding to be adjacent to the display panel; and
a third bonding layer covering the plurality of protruding members, including a metal, and being partially in contact with one of the plurality of pad electrodes, and
wherein a third contact area between the third bonding layer of each of the plurality of third bump electrodes and one of the plurality of pad electrodes is larger than the second contact area.

13. The display device of claim 1, wherein the first area is about 1.5 to about 3 times larger than the second area.

14. The display device of claim 1, wherein the number of the plurality of first bump electrodes included in the driving unit is less than the number of the plurality of second bump electrodes included in the driving unit.

15. The display device of claim 1, wherein the plurality of protruding members comprise a polymer material.

16. The display device of claim 1, wherein a width of each of the plurality of protruding members decreases as each of the plurality of protruding members approaches the display panel.

17. The display device of claim 1, wherein the plurality of second bump electrodes are disposed closer to the display region than the plurality of first bump electrodes.

18. A display device comprising:
a display panel comprising a display region in which pixels are disposed and a non-display region in which a plurality of pad electrodes are disposed; and
a driving unit disposed on the display panel and comprising a plurality of bump electrodes, each of the plurality of bump electrodes connecting to a corresponding pad electrode among the plurality of pad electrodes,
wherein the plurality of bump electrodes comprise:
a plurality of first bump electrodes arranged along a first direction; and
a plurality of second bump electrodes arranged along the first direction,
wherein the plurality of first bump electrodes are spaced apart from the display region with the plurality of second bump electrodes interposed between the plurality of first bump electrodes and the display region,
wherein each of the plurality of first bump electrodes and the plurality of second bump electrodes comprises:
a plurality of protruding members protruding to be adjacent to the display panel; and
a bonding layer covering the plurality of protruding members, the bonding layer of each of the plurality of first bump electrodes partially in contact with a first pad electrode among the plurality of pad electrodes and the bonding layer of each of the plurality of second bump electrodes partially in contact with a second pad electrode among the plurality of pad electrodes,
wherein a first area of each of the plurality of first bump electrodes is different from a second area of each of the plurality of second bump electrodes, and
wherein a first contact area between the bonding layer of each of the plurality of first bump electrodes and the first pad electrode is different from a second contact area between the bonding layer of each of the plurality of second bump electrodes and the second pad electrode.

19. The display device of claim 18,
wherein the first pad electrode overlaps each of the plurality of first bump electrodes on a plane, and the second pad electrode overlaps each of the plurality of second bump electrodes on the plane,
wherein each of the plurality of first bump electrodes comprises a plurality of first protruding members protruding to be adjacent to the display panel, and a first bonding layer covering the plurality of first protruding members, including a metal, and being partially in contact with the first pad electrode, and
wherein each of the plurality of second bump electrodes comprises a plurality of second protruding members protruding to be adjacent to the display panel and a second bonding layer covering the plurality of second protruding members, including a metal, and being partially in contact with the second pad electrode.

20. An electronic device comprising:
a display panel comprising a display region in which pixels are disposed and a non-display region in which a plurality of pad electrodes are disposed;
a driving unit disposed on the display panel and comprising a plurality of bump electrodes, each of the plurality of bump electrodes connecting to a corresponding pad electrode among the plurality of pad electrodes; and
a first adhesive layer disposed between the display panel and the driving unit and bonding the display panel to the driving unit,
wherein the first adhesive layer comprises a non-conductive film,
wherein the plurality of bump electrodes comprise a plurality of first bump electrodes arranged along a first direction and a plurality of second bump electrodes arranged along the first direction,
wherein each of the plurality of first bump electrodes and the plurality of second bump electrodes comprises:
a plurality of protruding members protruding to be adjacent to the display panel; and
a bonding layer covering the plurality of protruding members, the bonding layer of each of the plurality of first bump electrodes partially in contact with a first pad electrode among the plurality of pad electrodes and the bonding layer of each of the plurality of second bump electrodes partially in contact with a second pad electrode among the plurality of pad electrodes,
wherein a first area of each of the plurality of first bump electrodes is different from a second area of each of the plurality of second bump electrodes, and
wherein a first contact area between the bonding layer of each of the plurality of first bump electrodes and the first pad electrode is different from a second contact area between the bonding layer of each of the plurality of the second bump electrodes and the second pad electrode.
